(19) United States
(12) Patent Application Publication
(10) Pub. No.: US 2026/0077375 A1
(43) Pub. Date: Mar. 19, 2026

(54) COATING APPARATUS, DRYER, LIGHT IRRADIATION DEVICE AND COATING SYSTEM

(71) Applicant: ENATECH CORPORATION, Osaka (JP)

(72) Inventors: Hideto YOSHIZUKA, Osaka (JP); Akihito YAMAMOTO, Osaka (JP); Sho WATANABE, Osaka (JP)

(21) Appl. No.: 18/993,798

(22) PCT Filed: Sep. 28, 2023
(86) PCT No.: PCT/JP2023/035357

§ 371 Date: Nov. 25, 2025

(30) Foreign Application Priority Data
Jun. 10, 2022 (JP) 2022-161613

(51) Int. Cl. B05C 1/02; B05C 9/14; B05C 11/10; B05C 13/02; F26B 3/28

(52) U.S. Cl. CPC B05C 1/027; B05C 9/14; B05C 11/10; B05C 13/02; F26B 3/28

(57) ABSTRACT

A coating apparatus 10 for applying a film-forming liquid to a peripheral edge of a board while moving a board and a coating unit 20 relative to each other, wherein the coating unit 20 includes a coating mechanism 21 and an extension mechanism 30, and wherein the coating mechanism 21 has a coating part 22 for applying the film-forming liquid to at least a peripheral edge face of the board, and wherein the extension mechanism 30 has a coating part 22 for applying the film-forming liquid to at least a peripheral edge face of the board. The extension mechanism 30 has an extension part 31 that extends the film-forming liquid applied by the application part 22 to the peripheral edge face and the peripheral upper and lower faces of the board in the form of a thin film, and a force mechanism 34 that forces the extension part 31 toward the peripheral edge face and the peripheral upper and lower faces of the board, and the extension part 31 is configured to be removable without removing the force mechanism 34 from the extension mechanism 30.

### TECHNICAL FIELD

The present invention relates to a coating apparatus, dryer, light irradiation device, and coating system, and more particularly, to a coating apparatus which is able to apply liquid to the periphery of a board, dryer capable of drying and curing liquids applied to the periphery of the board, light irradiation device, and coating systems consisting of a combination of these apparatus.

### BACKGROUND ART

Printed circuit boards made of glass epoxy, composite, and paper phenolic materials are widely used as examples of boards for mounting electronic components. When these printed circuit boards are cut, fine dust consisting of epoxy resin or glass fibers is generated in the cut area. Such fine dust can cause contact failures in board circuits, and a decrease in quality, etc. Therefore, it is preferable to remove the dust created during the cutting of the board when the printed circuit board is manufactured. Even if the fine dust was once removed from the edge face of the cut part of the printed circuit board, the edge face of the printed circuit board is fragile, and there is a risk that the edge face may collapse and generate additional dust in the subsequent manufacturing process of the board, such as the etching process.

Therefore, the applicant has previously proposed a coating apparatus and a coating method that can prevent the collapse of the edge face of a board by applying the film-forming liquid to the edge face of the board to form a film (Patent Document 1) .

In the coating device described in Patent Document 1, a film-forming liquid is applied to the edge face of a board by moving a pair of coating rollers, which are positioned opposite each other so that they can sandwich the edge of the board, along the board periphery.

Furthermore, in recent years, demand for thin copper-clad laminated board (also called package board) with thicknesses ranging from several tens to several hundreds of micrometers has been increasing in order to accommodate thinner and more compact electronic devices.

For such thin board, it is not easy to apply the film-forming liquid only to the edge face of the board, and it was considered desirable to apply it to the periphery of the board, including the edge face, for example, in a framed form.

Therefore, the applicant has previously proposed a coating apparatus and a coating method that can prevent the collapse, etc. of the edge portion of a board by applying the film-forming liquid to the periphery, including the edge face of the board, in a framed manner to form a film (Patent Document 2) .

In the coating apparatus described in Patent Document 2, a liquid reservoir for collecting a film-forming liquid and a coating section for coating a thin film of the film-forming liquid adhering to the edge of a board that has passed through the liquid reservoir are provided on the opposite sides of the upper and lower pair of coating heads.

With the edge of the board inserted into the gap formed on the opposing faces of the pair of coating heads, the film-forming liquid is applied to the periphery of the board, including the edge faces, in a framed manner by moving the pair of coating heads along the periphery of the board.

Recently, the number of types of boards to be coated has increased, and the manufacturing and processing processes for these boards have also become more diverse. Depending on the type of board and its manufacturing process, the application form of the aforementioned film-forming liquid to the board has been diversifying, and there are cases where the coating apparatus described in the above-mentioned Patent Documents 1 and 2 cannot successfully handle such a situation.

For example, in the coating apparatus described in Patent Document 2, the film-forming liquid that adheres to the edge face of a board that has passed through the liquid reservoir and coating section of the pair of coating heads may drip onto the lower of the edge face of the board and go around the lower corners of the edge face, causing a slight puddle of liquid to form.

As a result, the thickness of the coating film at the lower corner of the edge face of the board after drying may become thicker in some parts, and the thickness of the coating film formed on the three sides of the board's periphery may not be uniform.

In the coating apparatus described in Patent Document 2, the board is inserted into the gap between a pair of coating heads equipped with a liquid reservoir, which also makes it difficult to apply the desired edge width when the edge width to be applied to the periphery of the board is narrow.

Therefore, the applicant has further proposed a coating apparatus that can accurately control the extremely narrow upper and lower application width of the film-forming liquid applied to the periphery of the board, including the edge faces of the board, and that can reliably form a thin coating of uniform thickness on the periphery of the board (Patent Document 3) .

In the coating apparatus described in Patent Document 3, the coating unit has a coating part that applies a film-forming liquid to at least a peripheral edge face of a board, and a extending part that extends the film-forming liquid applied by the coating part to the upper and lower peripheral faces of the board in the form of a thin film.

The extending part is equipped with an edge extending member, a narrow upper face extending member, and a lower face extending member, which enables uniform film thickness of the coating film formed on the three peripheral faces of the board and extremely narrow edge widths on the upper and lower faces of the peripheral area.

The applicant has also previously proposed a dryer capable of efficiently drying a plurality of boards with liquid coated on the edge or periphery of the board by the above coating apparatus, a light irradiation device capable of irradiating light for curing and drying the liquid on the edge or periphery of the board, and a coating system equipped with these devices (Patent Document 4) .

### Problems to Be Solved by the Invention

However, in the coating apparatus described in Patent Document 3, the extending part has a structure that makes it difficult to perform maintenance such as parts replacement, cleaning, and conservation, and maintenance work is not easy.

In the coating apparatus described in Patent Document 3, the first force mechanism comprising the extending part includes a shaft member and a first spring member inserted into the shaft member, and the shaft member is inserted into a first attaching member to which a top face extending member is attached and a second attaching member to which a lower face extending member is attached.

Therefore, part of the film-forming liquid removed from the board by the upper face extending member or the lower face extending member may enter the gap such as in the shaft hole of the first attaching member to which the shaft member is inserted.

In such a case, the film-forming liquid that has penetrated into the shaft hole, etc., gradually dries, which gradually increases the frictional resistance between the shaft member and the shaft hole of the first attaching member, making it difficult for the first attaching member to properly move up and down along the shaft member in a forceful motion.

As a result, the force that forces the top face extending member toward the lower face extending member may weaken and become unstable, and the uniformity of film thickness after extending may be reduced.

In the dryer described in Patent Document 4, multiple shelves are fixed in the drying chamber, a board holder is placed on each of these shelves, and an open/close door for carrying in and an open/close door for carrying out the boards corresponding to each shelf is provided on the side of the drying chamber. As a result, the number of parts that make up the drying chamber has increased, resulting in a complicated equipment structure.

In the dryer described above, when boards are carried in and out, the fork section for carrying in and the fork section for carrying out are controlled to be raised and lowered to the height position of the shelf to be carried in and out, respectively, and to be moved horizontally.

Therefore, the structure is such that the lifting and lowering means of the fork section for carrying in and the lifting and lowering means of the fork section for carrying out are installed on both sides of the drying chamber, which requires installation space for these lifting and lowering means, making it difficult to save space for the equipment.

In the light irradiation device described in Patent Document 4, the first light irradiation means is arranged at the top and lower positions of the transport means in an orientation that intersects the transport direction of the board, and the second light irradiation means is arranged at the top and lower positions of the transport means in an orientation that is parallel to the transport direction of the board, and the peripheral edge of the board being transported by the transport means is irradiated at a time when it passes through the irradiation areas of the first and second light irradiation means.

Therefore, it takes a long time to complete light irradiation to each side of the board, and it is difficult to uniformly irradiate each side of the board, which may result in uneven irradiation.

### PRIOR ART DOCUMENT

### Patent Document

Patent Document 1: International Publication No. 2010/137418
Patent Document 2: International Publication No. 2016/072250
Patent Document 3: Japanese Patent Application Laid-Open Publication No. 2022-99172
Patent Document 4: Japanese Patent Application Laid-Open Publication No. 2017-201219

### SUMMARY OF THE INVENTION

### Solution to Problem and Advantageous Effect of Invention

The present invention was developed in order to solve the above problem, and it is an object of the present invention to provide a coating apparatus that can easily replace and clean the extension part, excel in maintainability, and improve the stability of the extension operation by the extension part.

Another object of the present invention is to provide a light irradiation device that can uniformly and efficiently irradiate light to the edge face and periphery of each side of the board.

Another object of the present invention is to provide a coating system that includes the coating apparatus, the dryer and/or the light irradiation device, and that is easy to maintain and that can perform the processes of coating, drying and curing the film-forming liquid on the periphery, including the edge face of the board, in a space-saving and efficient manner.

In order to achieve the above object, a coating apparatus (1) for the present invention is characterized in that a coating apparatus for applying a film-forming liquid to the periphery of a board while moving the board and the coating unit relative to each other, wherein
the coating unit comprises an coating mechanism and an extension mechanism,
the coating mechanism has a coating part that applies the film-forming liquid to at least the peripheral edge face of the board,
the extension mechanism has an extension part that extends the film-forming liquid applied by the coating part into a thin film on the edge face of the periphery and the top and lower faces of the periphery of the board, and a force mechanism that forces the extension part towards the edge face of the periphery and the top and lower faces of the periphery of the board,
the extension part is removable without removing the force mechanism from the extension mechanism.

According to the coating apparatus (1), it is possible to remove the extension part from the extension mechanism without removing the force mechanism from the extension mechanism, allowing easy maintenance such as replacement of only the extension part or cleaning of the extension part, making the coating apparatus easy to maintain.

The coating apparatus (2) for the present invention is characterized in that, in the coating apparatus (1), the extension part is configured to be interchangeable with another extension part without removing the force mechanism from the extension mechanism.

According to the coating apparatus (2), since the extension part is configured to be interchangeable with another extension part without removing the force mechanism from the extension mechanism, the extension part can be replaced with another extension part flexibly according to changes in the type of board to be coated, coating conditions, and other factors, thereby improving the usability of the equipment. The another extension parts are, for example, extension parts of different widths of the film-forming liquid that are extended to the top and lower faces of the periphery of the board.

The coating apparatus (3) for the present invention is characterized in that, in the coating apparatus (1) or (2), the extension part comprises an top unit and a lower unit,
the force mechanism comprises;
a 1st supporter supporting said upper unit,
a 2nd supporter supporting said lower unit,
a 1st linear motion mechanism to which the 1st supporter and the 2nd support are each movably attached in a vertical direction,
a 2nd linear motion mechanism to which the 1st linear motion mechanism is movably attached in a horizontal direction orthogonal to the peripheral edge face of the board,
a 1st force part that forces the 1st supporter downwardly,
a 2nd force part that forces the 2nd supporter upwards; and
a 3rd force part that forces the 1st linear motion mechanism attached to
the 2nd linear motion mechanism towards the upper unit and the lower unit.

According to the coating apparatus (3), the upper unit is supported by the 1st supporter and the 1st supporter is forced downward by the 1st force part, and the lower unit is supported by the 2nd supporter and the 2nd supporter is forced upward by the 2nd force part. And the 1st supporter and the 2nd supporter are attached to the 1st linear motion mechanism, and the 1st linear motion mechanism attached to the 2nd linear motion mechanism is forced to the side of the upper unit and the lower unit by the 3rd force part.

Therefore the upper unit can be removed from the 1st supporter and the lower unit can be removed from the 2nd supporter separately without removing any of the 1st, 2nd, and 3rd force parts from the extension mechanism, and maintenance, etc. of the upper unit and the lower unit can be performed separately.

The coating apparatus (4) for the present invention is characterized in that, in the coating apparatus (3), the 1st supporter has a 1st linear motion part attached to the 1st linear motion mechanism and a horizontal plate strip protruding from the lower part of the 1st linear motion part,
the 2nd support part has a 2nd linear motion part attached to the 1st linear motion mechanism, a vertical plate protruding from the side of the 2nd linear motion part, and an axle protruding horizontally from the vertical plate,
the upper unit is detachably attached to the horizontal plate,
the lower unit is detachably attached to the vertical plate with the lower unit inserted into the axle.

According to the coating apparatus (4), the upper unit is removably attached to the horizontal plate, and the lower unit is removably attached to the vertical plate, with the lower unit inserted into the axle part.

Therefore, the upper unit can be removed from the horizontal plate without removing any of the 1st, 2nd, and 3rd force parts from the extension mechanism, and the lower unit can be removed from the vertical plate in the direction of the axis part.

Therefore, the upper unit and the lower unit can be easily removed without interfering with other equipment components.

The coating apparatus (5) for the present invention is characterized in that, in the coating apparatus (4), the upper unit comprises an upper block that is positioned above the horizontal plate, an L-shaped upper extension block that covers the upper and one side of the upper block, and a 1st attaching member that attaches the upper block and the upper extension block to the horizontal plate,
the lower unit comprising a lower block having an axle hole through which the axle is inserted, an L-shaped lower extension block that covers the lower face and one side of the lower block, a 2nd attaching member that is attached to the tip of the axle to which the lower block is inserted, and a 3rd attaching member that attach the lower extension block to the lower block,
the upper extension block and the lower extension block have facing faces on one side,
the facing faces are equipped with an upper face extension member that contacts the upper peripheral face of the bord, an edge face extension member that contacts the peripheral edge face of the bord, and a lower face extension member that contacts the lower peripheral face of the bord.

According to the coating apparatus (5), by the 1st attaching member, the upper block and the upper extension block can be detachably attached to the horizontal plate. The lower extension block can be attached to the lower block by the 3rd attaching member. By the 2nd attaching member, the lower block can be detachably attached to the vertical plate with the lower block inserted into the axle part.

Since an upper face extension member, an edge face extension member, and a lower face extension member are equipped with on the opposite faces of the upper extension block and the lower extension block, the width of the film-forming liquid stretched on the upper and lower faces can be easily changed, by replacing the upper extension block and the lower extension block according to changes in the board type, coating conditions, and the like.

The coating apparatus (6) for the present invention is characterized in that, in the coating apparatus (5), the lower block has a short tube protruding from the opening of the axle hole,
the short tube has a flange at its tip,
the axle part has a cutout formed on the tip side, a mooring formed on the outer circumference of the tip where the cutout is formed, and a taper formed on the tip side from the mooring,
the mooring is configured to be able to engage the opening of the flange,
the 2nd attaching member has a cavity that can accommodate the flange and the taper, a short tube port that can be inserted into the short tube and can be engaged with the flange, and an inclined stopper that can be pressed along the taper in the cavity.

According to the coating apparatus (6), to attach the lower block to the vertical plate, simply insert the axle part into the axle hole in the lower block and push the lower block to the side of the vertical plate until it is in a position where the axle part's mooring engages the opening in the flange.

To remove the lower block from the vertical plate, first push the 2nd attaching member toward the axle part. Then, the stopper of the 2nd attachment member is pressed against the taper of the axle part, the gap in the slit gradually narrows, the mooring disengages from the opening of the flange, and the mooring is pushed into the short tube.

Furthermore, when the 2nd attaching member is pulled from this state in the direction of pulling the 2nd attaching member from the axle part, the short tube port engages the flange, and the lower block can be pulled from the axle part and removed while remaining in this state.

Therefore, the lower block can be easily attached to the vertical plate by the motion of pushing the lower block in, and the lower block can be easily removed from the vertical plate by the simple motion of pushing and pulling the 2nd attachment member.

The coating apparatus (7) for the present invention, is characterized in that, in any of the coating apparatuses (1)˜(6), the coating part has a rotating shaft with a screw at its lower end, a coating roller with an annular groove on its outer circumference and an axle hole in the center through which the rotating shaft is inserted, a liquid supply part located close to the outer circumference of the coating roller to supply the film-forming liquid to the annular groove, and a collection part to collect the film-forming liquid dripping down from the coating roller,
the collection part has a threaded part that has a screw hole that can be screwed into the screw and fixes the coating roller to the rotating shaft,
a liquid receiver that is located below the threaded part, and a linkage that connects the threaded part and the liquid receiver so that their central axis are the same,
the coating roller and the collection part are attachable and detachable from the rotating shaft.

According to the coating apparatus (7), the coating roller is inserted into the rotating shaft, and the threaded part of the recovery part is screwed onto the screw at the lower end of the rotating shaft, so that the coating roller and the recovery part are attachable and detachable from the rotating shaft for easy maintenance such as replacement, cleaning, etc. of the coating roller. It is also possible to easily replace the coating roller with another coating roller having a different structure (e.g., height, depth, etc.) of the annular grooves according to changes in the type of board to be coated, coating conditions, etc.

The coating apparatus (8) for the present invention, is characterized in that, in any of the coating apparatuses (1)˜(7), it comprises:
a supporter that supports the board,
the coating units arranged around the supporter,
transport means for transporting each of these coating units along the edge of the bord supported by the supporter,
a coating control unit that controls the operation of each of these transporting means and each of the coating units, wherein
the coating control unit perform controls by transporting each coating unit along the edge of the bord by each of the transport means,
while applying the film-forming liquid to at least the peripheral edge face of the bord by the coating part of the coating units,
while extending the film-forming liquid to the peripheral edge face and the upper and lower faces of the peripheral portion of the bord by the extension part in a thin film shape.

According to the coating apparatus (8), the periphery of each side of the board is coated in parallel by a plurality of coating units, which significantly reduces the time required to coat the entire periphery of the board, thereby increasing coating efficiency. Maintenance such as replacement and cleaning of the extension part of each of the multiple coating units can be easily performed, thereby increasing the work efficiency of the maintenance.

A dryer (1) for the present invention is characterized by having a drying furnace for drying a bord coated with a film-forming liquid by a coating apparatus, comprises:
a housing shelf with multiple shelves on which the bord is placed, located in the drying furnace,
a carrying-in entrance opening/closing part provided on the side of the board carrying-in side of the drying furnace that opens and closes the carrying-in entrance where the board carrying-in means is put in and out,
a carrying-out entrance opening/closing part provided on the side of the board carrying-out side of the drying furnace that opens and closes the carrying-out entrance where the board carrying-out means is put in and out,
an opening/closing control part that controls the opening/closing operations by the carrying-in entrance opening/closing part and the carrying-out entrance opening/closing part,
an elevating mechanism to lift and lower the housing shelf
an elevating controller that controls the lifting and lowering operation of the housing shelf by the elevating mechanism.

According to the dryer (1), since the housing shelf is raised and lowered in the drying furnace during carry-in and carry-out of the board, there is no need to raise and lower the means for carrying in and carrying out boards, thereby simplifying the equipment structure, saving space and making the equipment more compact.

The dryer (2) for the present invention is characterized in that, in the dryer (1), the elevation control unit controls the elevation operation of the housing shelves so that, at the time of bord carry in, the shelves to which the bord are to be carry in are positioned at the height of the carry in entrance among the multiple shelves, and then the bord that are brought in by the bord carry in means are placed on the shelves,
and controls the elevation operation of the housing shelves so that, at the time of bord carry out, the shelves to which the bord are to be carry out are positioned at the height of the carry out entrance among the multiple shelves, and then the bord on the shelves are transferred to the bord carry out means.

According to the dryer (2), by controlling the lifting and lowering operation of the housing shelf by the elevating controller, it is possible to accurately place the board that has been carried in from the carry in entrance by the board carry in means on the shelf, and to accurately transfer the board on the shelf to the board carry out means, thereby making it possible to perform the carrying in and carrying out operation of the board efficiently.

The dryer (3) for the present invention is characterized in that, in the dryer (1) or (2), the elevating mechanism comprises:
a supporter for the housing shelf
an elevating driver to elevate the supporter
a shelf position detector to detect the presence of the shelf at the height position of the carry in entrance or the carry out entrance.

According to the dryer (3), the shelf position detector detects which of the multiple shelves is at the height position of the carry-in entrance or the carry-out entrance, so that the shelf on which the board to be carried in by the board carry in means or the shelf on which the board to be transferred to the board carry-out means is placed can be accurately detected, thereby enhancing the accuracy of the board carry-in and carry-out operations.

A light irradiation device (1) for the present invention is characterized in that irradiating light to the periphery of a bord on which a film-forming liquid has been applied by a coating apparatus to cure the film-forming liquid, comprises:
a elevating stage that can be elevated with the board placed on it,
a light irradiation unit that is positioned around elevating space of the elevating stage and irradiates light to the periphery of the board,
a rotation mechanism to rotate the light irradiation unit so that the light irradiation face of the light irradiation unit is in close proximity to and facing at least the upper face of the periphery and the lower face of the periphery of the board.

According to the light irradiation device (1), the light irradiation unit is arranged around the elevation space of the elevating stage, and the rotation mechanism is configured to rotate the light irradiation unit so that the light irradiation face of the light irradiation unit is in close contact with at least the upper face of the peripheral edge and the lower face of the peripheral edge of the board placed on the elevating stage.

Therefore, it is not necessary to move the board horizontally during light irradiation, and light irradiation can be uniformly and efficiently applied to the upper and lower and the edge faces of the periphery of each side of the board, enabling the film-forming liquid to be cured uniformly and efficiently.

The light irradiation device (2) for the present invention is characterized in that, in the light irradiation device (1), the light irradiation units comprises a 1st light irradiation unit pair and a 2nd light irradiation unit pair arranged in opposing positions at different heights around the elevating space, wherein
the 1st light irradiation units pair is arranged in a direction parallel to the board transport direction,
the 2nd light irradiation units pair is positioned in a direction orthogonal to the board transport direction, wherein
the rotation mechanism comprising a 1st rotation mechanism pair that rotates the 1st light irradiation unit pair and a 2nd rotating mechanism pair that rotates the 2nd light irradiation unit pair.

According to the light irradiation device (2) described above, by moving the elevating stage on which the board is placed to the height position of the first light irradiation unit pair and rotating the 1st light irradiation unit pair by the 1st rotation mechanism pair, the upper face of the peripheral edge, the edge face of the peripheral edge, and the lower face of the peripheral edge of two sides of the board in parallel relationship with the transport direction of the board are uniformly and efficiently irradiated.

By moving the elevating stage on which the board is placed to the height position of the 2nd light irradiation unit pair, which has a different height position from that of the 1st light irradiation unit pair, and by rotating the 2nd light irradiation unit pair with the 2nd rotation mechanism pair, the light irradiation can be uniformly and efficiently applied to the upper face of the peripheral edge, the edge face of the peripheral edge, and the lower face of the peripheral edge of the two sides of the board that are orthogonal to the transport direction of the board.

The light irradiation device (3) for the present invention is characterized in that, in the light irradiation device (2), it comprises:
a transport mechanism for advancing or retracting at least one of the 2nd rotation mechanisms pair in the transport direction of the board.

According to the light irradiation device (3) described above, at least one of the 2nd rotation mechanism pairs can be moved back and forth in the board transport direction by the transport mechanism, thereby adjusting the placement interval of the 2nd rotation mechanism pair according to the size of the board or other factors.

The light irradiation device (4) for the present invention, is characterized in that, in any of the light irradiation device (1)˜(3),
a conveyor for transporting the board is located below the elevating stage,
the conveyor has narrow width rollers arranged in the direction of conveyance of the board,
the elevating stage has an aperture at a position opposite to the narrow width rollers of the conveyor to bring these narrow width rollers to the upper of the elevating stage.

According to the light irradiation device (4), when the elevating stage is lowered, the narrow width rollers of the conveyer can be faced through the opening of the elevating stage. Therefore, the board on the elevating stage can be promptly and efficiently transferred to the conveyer simply by lowering the elevating stage.

The light irradiation device (5) for the present invention, is characterized in that, in any of the light irradiation device (1)˜(4), it comprises:
positioning means for positioning the board before moving it onto the elevating stage,
transport means for moving the board, which has been positioned as specified by the positioning means, onto the elevating stage.

According to the light irradiation device (5), the position of the board is adjusted by the positioning means before moving the board onto the elevating stage, and the board with the adjustment made can be moved onto the elevating stage by the transport means. Therefore, the board can be placed on the elevating stage in an accurately positioned state, and light irradiation by the light irradiation unit to the upper face of the peripheral edge, the edge face of the peripheral edge, and the lower face of the peripheral edge of the board can be accurately performed.

The light irradiation device (6) for the present invention is characterized in that, in the light irradiation device (5), the positioning means comprises:
upper table unit that can rotate with the board placed on it,
a lower table unit located under the upper table unit and capable of moving the upper table unit linearly in a predetermined direction,
a corner detection means for detecting the orientation and position of a corner of a board placed on the upper table unit, and
a positioning control part that drives the upper table unit and/or the lower table unit so that the orientation and position of the corners of the board detected by the corner detection means are in the specified orientation and position.

According to the light irradiation device (6), the orientation and/or position of the board can be adjusted by controlling the upper table unit and/or the lower table unit so that the orientation and position of the corners of the board detected by the corner detection means are in the predetermined orientation and position.

The light irradiation device (7) for the present invention is characterized in that, in the light irradiation device (6), the upper table unit comprises:
a place table on which the board is placed,
a rotation axis provided on one corner lower face of the place table,
a roller provided on the other corner lower face of the place table, and
a rotation driver to rotate the place table around the rotation axis,
wherein the lower table comprises:
a support table that supports the place table, and
a linear motion mechanism part that can adjust the support table in a direction perpendicular to the direction of movement of the board,
wherein the rotation axis and the rotation drive are attached to the support table.

According to the light irradiation device (7), the upper table unit is configured to allow fine adjustment of the orientation (i.e., angle) of the board by rotating the place table by the rotation driver around the rotation axis. The lower table unit enables fine position adjustment of the support table, which supports the place table, in a direction perpendicular to the direction of board movement. Therefore, the orientation and positioning accuracy of the board can be improved.

The light irradiation device (8) for the present invention is characterized in that, in the light irradiation device (6) or (7),
the corner detection means comprises:
   a lighting part that illuminates from below toward the corners of the board,
an imaging capture part provided in a position opposite to the lighting part, which captures images of the corners of the board from above, wherein
   the positioning control part drives the upper table unit and/or the lower table unit so that the orientation and position of the corners of the board as imaged by the image capture part are in a predetermined orientation and position.

According to the light irradiation device (8), since it is configured to capture images of the corners of the board illuminated by the lighting part at the image capture part, the direction and position of the corners of the board can be accurately detected by the captured images.

The positioning control part drives the upper table unit and/or the lower table unit to adjust the orientation and/or position of the board so that the orientation and position of the corners of the board as imaged by the image capture part become the predetermined orientation and position. Therefore, the orientation and/or position of the board can be adjusted with even greater precision.

The coating system (1) for the present invention is characterized in that, it comprises any of the coating apparatus (1)˜(8) and any of the dryer (9)˜(11).

According to the coating system (1), it is possible to construct a more compact coating system with better maintainability than before, which achieves the effects of any of the coating apparatus (1)˜(8) and any of the dryer (1)˜(3).

The coating system (2) for the present invention is characterized in that, it comprises any of the coating apparatus (1) ˜(8) and any of the light irradiation device (1)˜(8).

According to the coating system (2), it is possible to construct a coating system that is easier to maintain than conventional systems, saves space, and performs curing treatment by light irradiation more efficiently, which has the effects of any of the coating apparatus (1)˜(8) and any of the light irradiation devices (1)˜(8).

The coating system (3) is characterized in that it comprises any of the coating apparatus (1)˜(8), any of the dryers (1)˜(3), and any of the light irradiation devices (1)˜(8).

According to the coating system (3), it is possible to construct a coating system that is easier to maintain than conventional systems, saves space, and performs drying and curing by light irradiation more efficiently than conventional systems by achieving the effects of any of the coating apparatus (1)˜(8), any of the dryer (1)˜(3), and any of the light irradiation devices (1)˜(8).

### BRIEF DESCRIPTION OF DRAWINGS

FIG. 1 is a block diagram showing an essential part of a coating system according to an embodiment of the present invention;

FIG. 2 is a schematic plan view showing an essential part of a coating apparatus according to an embodiment;

FIG. 3 is a slanted view showing an essential part of a coating unit;

FIG. 4 is a IV-IV partial cross-sectional slanted view in FIG. 3;

FIG. 5 is a V-V partial cross-sectional side view in FIG. 3;

FIG. 6 is a VI-VI partial cross-sectional view in FIG. 5;

FIG. 7 is a VII-VII partial cross-sectional view in FIG. 5;

FIG. 8 is a slanted view showing the state of the extensions part removed from the extension mechanism;

FIG. 9 is a partially enlarged cross-sectional view showing another attaching configuration example of the 2nd attaching member,
(a) is showing the state of the lower block is attached to the attaching axle, (b) and (c) are showing the state of the lower block in the process of being removed from the attaching axle;

FIG. 10 is a partial cross-sectional front view showing an essential part of a dryer according to an embodiment;

FIG. 11 is a partial cross-sectional side view showing an essential part of a dryer;

FIG. 12 is a XII-XII partial cross-sectional view in FIG. 10;

FIG. 13 is a XIII-XIII partial cross-sectional view in FIG. 11;

FIG. 14 is a plan view showing the state in which the carry-in forks are inserted into the drying furnace;

FIG. 15 is a slanted view showing an essential part of a light irradiation unit of a UV irradiation device according to an embodiment;

FIG. 16 is a plan view showing an essential part of a positioning unit of a UV irradiation device;

FIG. 17 is a side view showing an essential part of a positioning unit;

FIG. 18 is a partial cross-sectional side view showing light irradiation operation by the 1st light irradiation unit pair;

FIG. 19 is a partial cross-sectional side view showing light irradiation operation by the 2nd light irradiation unit pair.

### DESCRIPTION OF EMBODIMENTS

### The preferred embodiments of the coating apparatus, the dryer, the light irradiation device, and the coating system according to the present invention are described below by reference to the Figures.

The following embodiments of the invention are suitable specific examples of the invention and are subject to various technically preferred limitations, but the scope of the invention is not limited to these embodiments unless specifically stated to limit the invention in the following description.

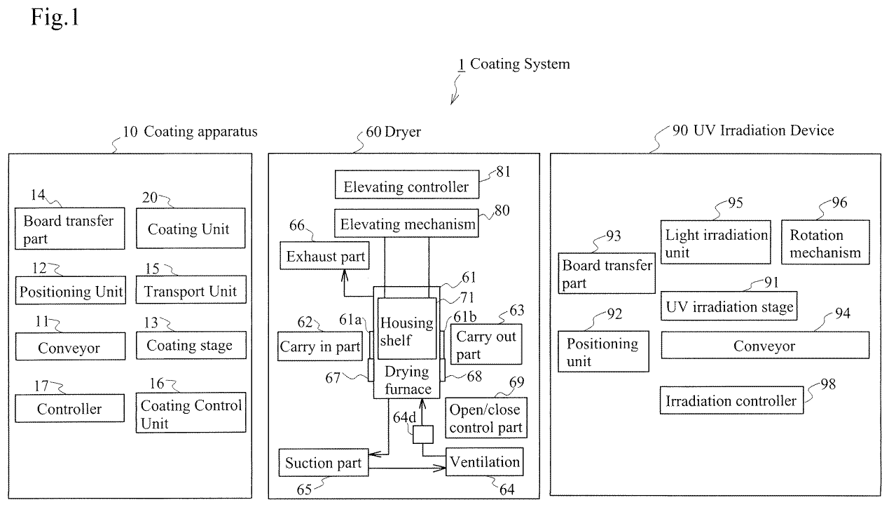

FIG. 1 is a block diagram showing an essential part of a coating system according to an embodiment of the present invention.

Coating system 1 comprises a coating apparatus 10, a dryer 60, and a UV irradiation device 90. The UV irradiation device 90 is an example of a light irradiation device.

The coating apparatus 10 is an apparatus for applying the film-forming liquid to the periphery (also called the outer edge) of the board while moving a coating unit 20 relative to the board.

The boards to be coated are so-called electronic circuit boards, such as printed wiring boards and module boards, for example. The materials used to construct the board are not particularly limited. For example, boards made of various materials such as copper-clad laminated board, aluminum board, glass board, or ceramic board can be the object to be coated. The size of the board is also not limited, but for example, a rectangular shape of around 400 to 800 mm in length and width, with a thickness of several tens of micrometers to several millimeters, can be the target of the coating.

The film-forming liquid is a liquid used to form a thin coating (thickness after curing, e.g., around 10 μm to 200 μm) on the periphery of the board. The film-forming liquid is used to prevent the generation of dust due to the collapse of the edge portion of the board or to reinforce the periphery of the board with the coating film to improve the handling of the board in the subsequent process and to reduce the incidence of defective boards.

As the film-forming liquid, it is preferable to use a mixture of multiple resin components that have properties (resistance to acid and/or alkali) that do not peel off in the board treatment process (etching process, plating process, etc.) and that have excellent adhesion to the board face, etc. For example, various types of liquids prepared according to the intended use, such as coating agents containing aqueous urethane resins, aqueous styrene resins, and aqueous thickeners, can be used against a solvent in an aqueous medium. The viscosity of the film-forming liquid is adjusted according to the film thickness and edge width to be applied.

The coating apparatus 10 has a conveyor 11 for transporting boards into the machine, a positioning unit 12 for positioning the incoming boards, a coating stage 13 for supporting the boards, and a board transfer part 14 for transferring the boards.

The coating apparatus 10 further comprises the coating unit 20 arranged around the coating stage 13, a transport unit 15 that moves the coating unit 20 along the edges of the board, a coating control unit 16 that controls the operation of each of these parts, and a controller 17.

The coating unit 20 has the function of applying the film-forming liquid to the periphery of the board placed on the coating stage 13.

The controller 17 is equipped with an operation panel for inputting settings such as operating conditions for each part of coating system 1 and for inputting operations to operate each part.

The conveyor 11 consists, for example, of a roller conveyor system. the positioning unit 12 consists, for example, of a device equipped with board clamps (not shown) on both sides of the conveyor 11 in the width direction and a mechanism that lightly clamps both sides of the board on the conveyor 11 with the board clamps to position and place the board in a given position.

The board transfer part 14 has the function of transferring the board positioned at the positioning unit 12 to the coating stage 13 and the board applied by the coating unit 20 on the coating stage 13 to the carry-in part 62 of the dryer 60.

The board transfer part 14 comprises, for example, a board holding section equipped with a plurality of suction portions that suck and hold a board, a horizontal movement mechanism that reciprocates the board holding section in the board transport direction, and a vertical movement mechanism that reciprocates the board holding section in the vertical direction (both not shown). the coating unit 20 and other specific configurations are described below.

The dryer 60 is a device for drying a board with film-forming liquid applied to the periphery by the coating apparatus 10.

The dryer 60 has a drying furnace 61 for drying boards, the carry-in part 62 for carrying in boards from a carry-in entrance 61a on the side of the board loading side of the drying furnace 61, and a carry-out part 63 for carrying out boards from a carry-out entrance 61b on the side of the board carry-out side of the drying furnace 61.

The dryer 60 is further equipped with a ventilation 64 for supplying air (hot air) to the drying furnace 61, a suction part 65 for suction of gas in the drying furnace 61, and an exhaust part 66 for exhausting some of the gas in the drying furnace 61. A dust collection filter 64d is provided between the ventilation 64 and the drying furnace 61.

The housing shelf 71 is arranged in the drying furnace 61 with multiple shelves on which boards are placed, the dryer 60 is equipped with a elevating mechanism 80 that raises and lowers the housing shelf 71 and a elevating controller 81 that controls the raising and lowering movement of the housing shelf 71 by the elevating mechanism 80.

On the side of the board-carry-in side of the drying furnace 61, there is a carry-in entrance opening/closing part 67 that opens and closes the carry-in entrance 61a, and on the side of the board-carry-out side of the drying furnace 61, there is a carry-out entrance opening/closing part 68 that opens and closes the carry-out entrance 61b. The dryer 60 is equipped with a open/close control part 69 that controls the opening and closing operation by the carry-in entrance opening/closing part 67 and the carry-out entrance opening/closing part 68. The drying furnace 61 and other specific configurations are described below.

The UV irradiation device 90 is a device for curing the film-forming liquid by irradiating UV rays to the periphery of the board, which is dried by the dryer 60 after the film-forming liquid has been applied by the coating apparatus 10.

The UV irradiation device 90 has a positioning unit 92 that positions the board transferred from the dryer 60 and an UV irradiation stage 91 that can be raised and lowered with the board transferred from the positioning unit 92 being placed on it.

The UV irradiation device 90 is further equipped with a board transfer part 93 and a conveyor 94. The board transfer part 93 has the function of transferring boards carried out by the carry-out part 63 of the dryer 60 to the positioning unit 92 and of transferring boards that have been positioned in a predetermined manner at the positioning unit 92 to the UV irradiation stage 91. The conveyor 94 is located below the UV irradiation stage 91 and functions to carry out the boards on the UV irradiation stage 91.

In addition, the UV irradiation device 90 consists of a light irradiation unit 95, a rotation mechanism 96, and a irradiation controller 98 that control the operation of each of these parts. The light irradiation unit 95 is positioned around the elevating space of the UV irradiation stage 91 and functions to irradiate the periphery of the board with UV rays. The rotation mechanism 96 functions to rotate the light irradiation unit 95 so that the light-irradiated face of the light irradiation unit 95 is in close proximity and opposition to at least the upper face of the periphery and the lower face of the periphery of the board. The specific configurations of the positioning unit 92, the light irradiation unit 95, etc. are described below.

In coating system 1, first, at the coating apparatus 10, the film-forming liquid is applied to at least the peripheral edge face of the board, and the applied film-forming liquid is extended to the peripheral edge face and the upper and lower faces of the peripheral edge of the board in the form of a thin film.

Next, at the dryer 60, the board on which the film-forming liquid has been applied and stretched in the coating apparatus 10 is brought into the drying furnace 61, and the process of drying the film-forming liquid stretched in a thin film around the periphery of the board is carried out.

Then, at the UV irradiation device 90, the process of curing the film-forming liquid stretched into a thin film is carried out by irradiating the periphery of the board that has undergone the drying process at the dryer 60 with UV rays.

The following is a description of the coating apparatus that make up the coating system according to an embodiment.

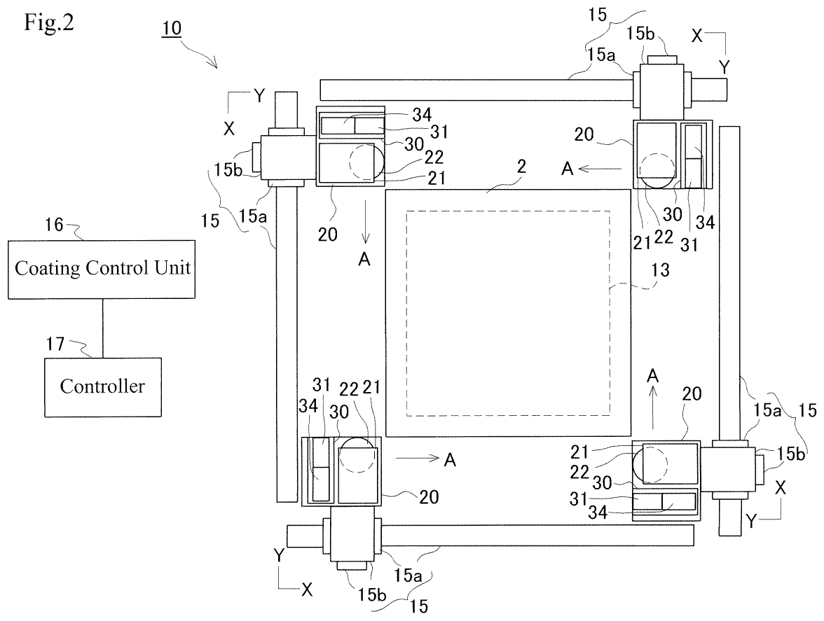

FIG. 2 is a schematic plan view showing an essential part of a coating apparatus according to an embodiment.

The coating apparatus 10 consists of the coating stage 13, four coating unit 20 arranged around the coating stage 13, four transport unit 15 that move these coating unit 20 along each side of 2, the coating control unit 16, and the controller 17.

In the coating apparatus 10, the configuration consists of four units of 20, which apply the periphery of the four sides of a board 2 in parallel at the same time. In another configuration example, the four sides of 2 may be configured to be applied in sequence by one coating unit 20, the coating unit 20 should be equipped with at least one or more of the coating apparatus 10.

Each coating unit 20 consists of a coating mechanism 21 and a extension mechanism 30. The coating mechanism 21 has a coating part 22 that applies a film-forming liquid to at least the peripheral edge face of the board 2. The extension mechanism 30 has an extension part 31 and a force mechanism 34. The extension part 31 is configured to extend the film-forming liquid applied to at least the peripheral edge face of the board 2 by the coating part 22 to a thin film on the peripheral edge face and the upper and lower faces of the peripheral edge. The force mechanism 34 has a configuration that forces the extension part 31 toward the edge of the periphery and the upper and lower faces of the periphery of the board 2.

One of the features of the coating apparatus 10 according to an embodiment is that the coating unit 20 is configured so that the extension part 31 portion can be removed without having to remove the force mechanism 34 from the extension mechanism 30. The specific configurations of the coating mechanism 21 and the extension mechanism 30 are described below.

The coating control unit 16 controls the operation of each part of each coating unit 20 and also controls the movement of each coating unit 20 along the sides of the board 2 (in the direction of arrow A) by each transport unit 15.

In addition to controlling the operation of each coating unit 20 and each transport unit 15, the coating control unit 16 may also have the function of controlling the operation of each part of the device, such as controlling the operation of the coating stage 13 (e.g., elevation control). The coating control unit 16 comprises, for example, a microcontroller, a driver circuit, a memory unit, and a power supply unit (all not shown).

The coating stage 13 is supported from below by a lifting mechanism (not shown) that allows it to be raised and lowered. A suction mechanism (not shown) may be provided on the coating stage 13, in which case 2 can be adsorbed to the upper face of the coating stage 13. As the adsorption mechanism, for example, a configuration in which a vacuum pump is connected via air tubes to a plurality of air intake holes in the coating stage 13 is employed. The board 2 are placed in position on the conveyor 11 to the coating stage 13 by the board transfer part 14.

Each transport unit 15 is arranged in a manner surrounding the coating stage 13 and consists of, for example, an orthogonal robot and includes a X-axis linear motion mechanism 15a and a Y-axis linear motion mechanism 15b attached to the X-axis linear motion mechanism 15a.

The X-axis linear motion mechanism 15a is a device for moving the coating unit 20 along the sides of the board 2 (in the X-axis direction), and comprises, for example, an X-axis cylinder arranged parallel to each side of the coating stage 13 and an X-axis slider that slides on the X-axis cylinder.

The Y-axis linear motion mechanism 15b is a device for moving the coating unit 20 in the direction perpendicular to the sides of the board 2 (Y-axis direction). The Y-axis linear motion mechanism 15b consists of a Y-axis cylinder attached to the X-axis slider of the X-axis linear motion mechanism 15a and a Y-axis slider that slides on the Y-axis cylinder.

The controller 17 can accept various inputs, such as setting operating conditions for each part of the device, operating instructions for each part, and switching operating modes. Operation and setting signals input via the controller 17 are output to the coating control unit 16. For example, the controller 17 allows the user to set the operating conditions of each part, such as the initial position of the coating unit 20, the movement speed by the transport unit 15, and the supply speed of the film-forming liquid by the coating unit 20.

In the above configuration the coating apparatus 10, the coating control unit 16 controls each coating unit 20 to move along each edge of the board 2 and each coating part 22 to apply the film-forming liquid to at least the peripheral edge face of the board 2 (coating process).

In parallel with the above application process, the coating control unit 16 controls the movement of each coating unit 20 along each side of the board 2 with the extension part 31 being forced by the force mechanism 34 toward the edge of the peripheral edge and the upper and lower of the peripheral edge of the board, i.e., with the extension part 31 pressed against the edge of the peripheral edge and the upper and lower of the peripheral edge of the board, the coating control unit 16 controls (extension process) to extend the film-forming liquid applied in the above application process to the edge face of the periphery and the upper and lower faces of the periphery of the board in the form of a thin film by the extension mechanism 30.

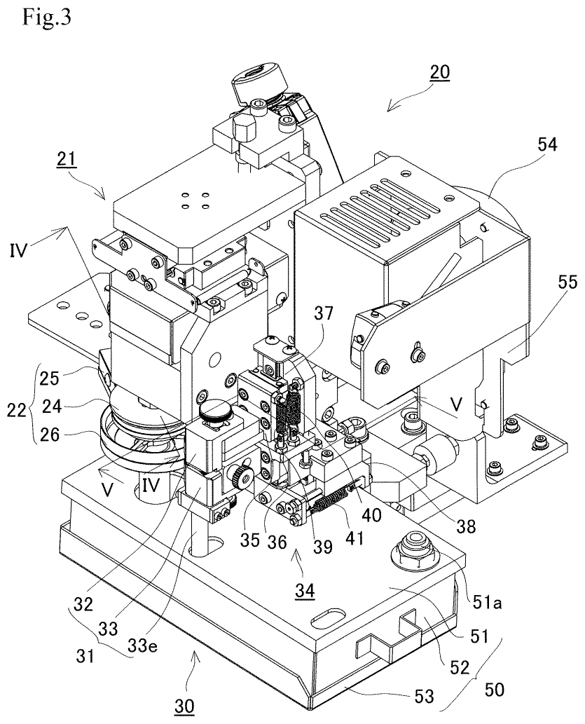

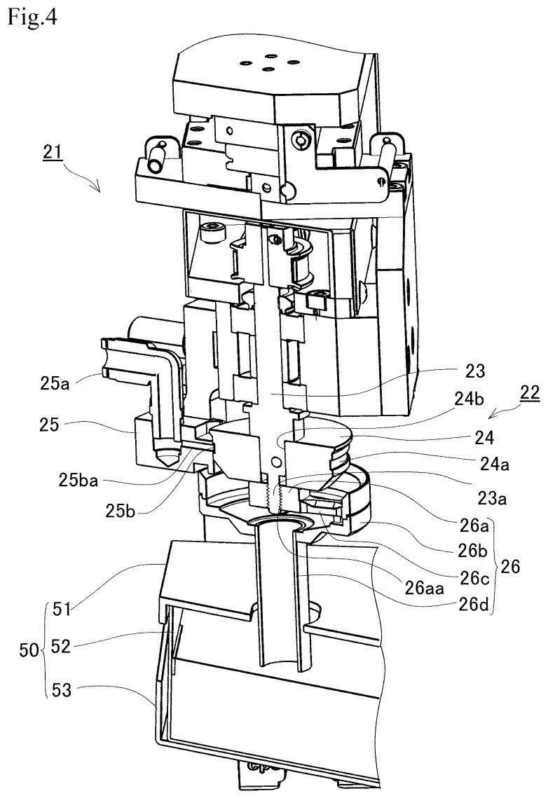

FIG. 3 is a slanted view showing an essential part of a coating unit 20, FIG. 4 is a IV-IV partial cross-sectional slanted view in FIG. 3, showing an essential part of the coating mechanism 21. For simplification of the drawing, the hatching of the cross section of the coating part is omitted.

The coating unit 20 consists of the coating mechanism 21 with the coating part 22 and the extension mechanism 30 with the extension part 31 and the force mechanism 34, with the extension part 31 removable without removing the force mechanism 34 from the extension mechanism 30.

The coating unit 20 further has a liquid container 50 in which the film-forming liquid is contained and a transfer pump 54 that transfers the film-forming liquid from the liquid container 50 to the coating part 22 via tubing (not shown).

These the coating mechanism 21, the extension mechanism 30, the liquid container 50, and the transfer pump 54 are assembled and integrated into a attaching member 55 attached to the Y-axis linear motion mechanism 15b of the transport unit 15 (see FIG. 2).

The liquid container 50 is located below the coating mechanism 21 and the extension mechanism 30 and has a lid 51, an under box 52, and a box receiving base 53 on which the under box 52 is placed. The box receiving base 53 is attached at a slight incline so that the film-forming liquid in the under box 52 flows in the direction of the coating mechanism 21 to the extension mechanism 30. The lid 51 is provided with a tube attachment 51a, and a tube (not shown) connected to the transfer pump 54 is attached to the tube attachment 51a. The liquid container 50 contains the film-forming liquid collected at the coating mechanism 21 and the extension mechanism 30, and the film-forming liquid is circulated through the coating unit 20 to be reused.

Next, the configuration of the coating mechanism 21 is described. As shown in FIGS. 3 and 4, the coating part 22 equipped with the coating mechanism 21 consists of a rotating shaft 23, a coating roller 24, the liquid supply part 25, and a collection part 26 that rotate under drive power from a drive motor (not shown). A screw 23a is formed at the lower end of the rotating shaft 23.

The coating roller 24 has an approximately disk shape, with a annular groove 24a formed on the outer periphery and an axle hole 24b in the center through which the rotating shaft 23 is inserted. The annular groove 24a has a roughly U-shaped cross-section, but this shape is not limited to this. The width and depth of the groove in 24a can be set as appropriate according to the type and thickness of the object to be coated, the width of the extension to the upper and lower faces of the periphery of 2.

The coating apparatus 10 may be individually equipped with the coating roller 24, which is equipped with the annular groove 24a for the extension widths of 1 mm, 3 mm, 5 mm, and 7 mm. According to this configuration, it is possible to replace the coating roller 24 as appropriate according to the conditions of the extension width, etc.

The coating roller 24 is configured to be driven at a predetermined speed by the drive motor. The predetermined speed is adjusted to a rotational speed that matches the relative moving speed with 2, for example.

A liquid supply part 25 is a component that is installed close to the outer circumference of the coating roller 24 and is used to supply the film-forming liquid to the annular groove 24a. The liquid supply part 25 is composed of a tube attachment 25a, a liquid ejection part 25b, and a contact piece (not shown).

The tube attachment 25a is made up of L-shaped tubes to which a tube (not shown) from the transfer pump 54 is attached. A nozzle hole 25ba is formed in a liquid ejection part 25b. The nozzle hole 25ba is a fluid channel formed to the opposite side face of from the tube attachment 25a to the annular groove 24a of the coating roller 24. The abutting plate is arranged adjacent to the liquid ejection part 25b and attached with its tip abutting against the outer circumference of the coating roller 24.

The collection part 26 is a component for collecting the film-forming liquid that drips down from the coating roller 24. The collection part 26 has a threaded part 26a, which fixes the coating roller 24 to the rotating shaft 23, a liquid receiver 26b, which is installed below the threaded part 26a, and a linkage 26c, which connects the threaded part 26a and the liquid receiver 26b so that their central axes are the same.

The threaded part 26a has a screw hole 26aa that can be screwed into the screw 23a of the rotating shaft 23. the liquid receiver 26b is formed in the shape of a dish with a diameter larger than the coating roller 24, and a tube 26d extends downward from the central hole. The lower end of the tube 26d is inserted into the liquid container 50, and the film-forming liquid that drips from the coating roller 24 to the liquid receiver 26b is collected in the liquid container 50 through the tube 26d. The screw 23a is constructed with a reverse thread to prevent the threaded part 26a from loosening due to the rotation of the rotating shaft 23, and the screw hole 26aa is constructed with a reverse threaded hole.

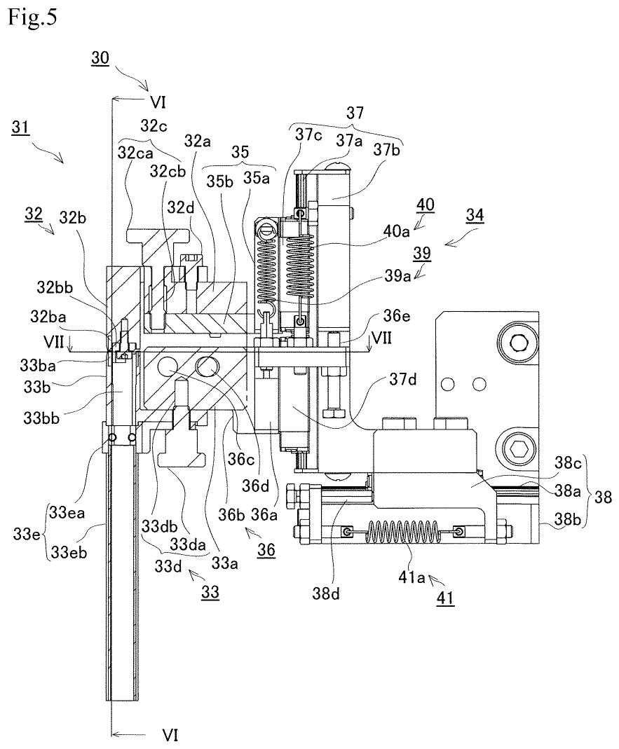

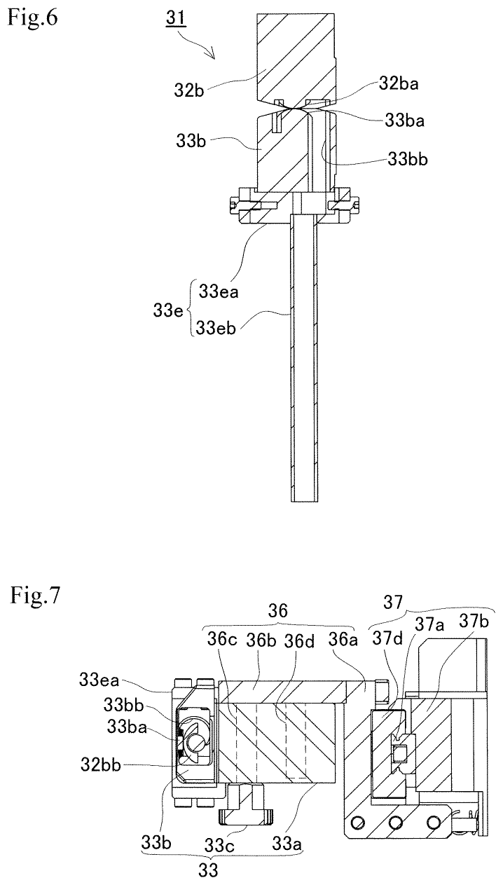

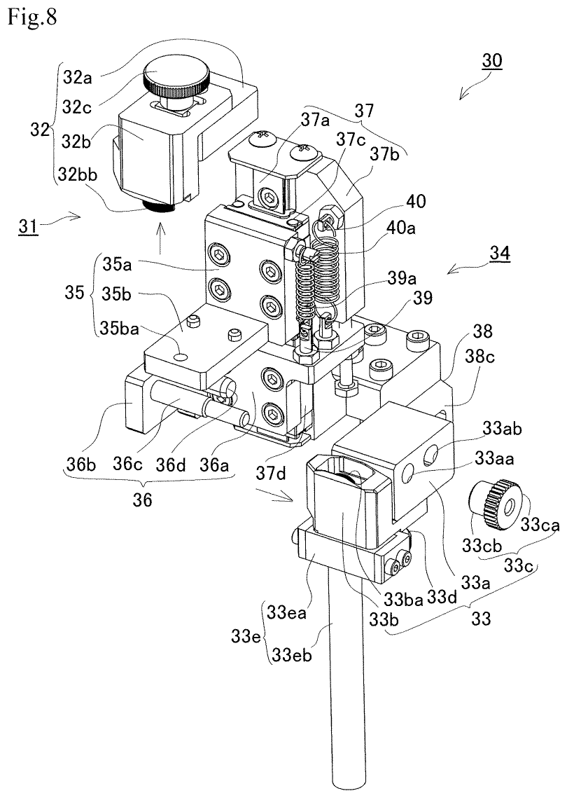

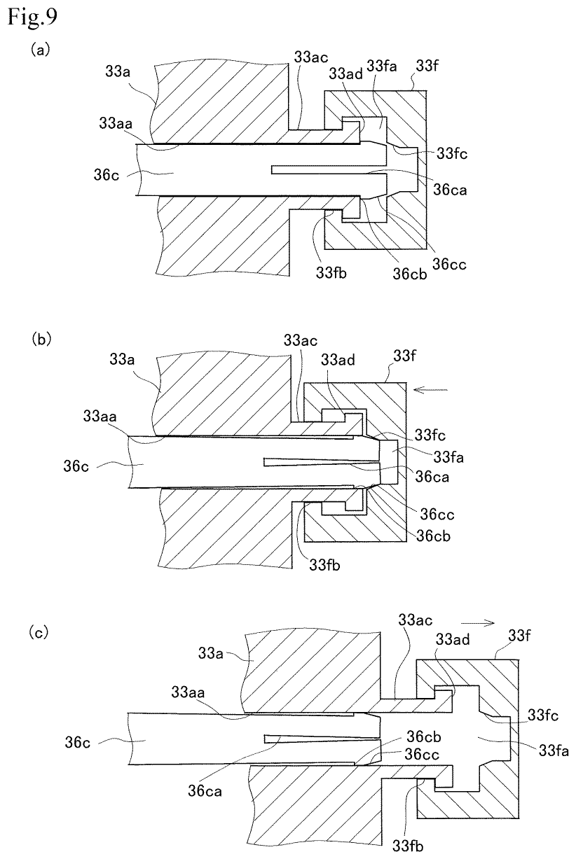

Next, the composition of the extension mechanism 30 will be explained. FIG. 5 is a V-V partial cross-sectional side view in FIG. 3, showing an essential part of the extension mechanism 30. FIG. 6 is a VI-VI partial cross-sectional view in FIG. 5, showing an essential part of an upper extension block 32b and a lower extension block 33b. FIG. 7 is a VII-VII partial cross-sectional view in FIG. 5, showing an essential part of a lower unit 33, the 2nd supporter 36, the 1st linear motion mechanism 37. FIG. 8 is a slanted view showing the state of the extensions part 31 removed from the extension mechanism 30.

As shown in FIGS. 3, 5, and 8, the extension mechanism 30 is composed of the extension part 31 and the force mechanism 34. The extension part 31 has a structure that extends the film-forming liquid applied to at least the peripheral edge face of the board in a thin film form to the peripheral edge face and the upper and lower faces of the board. In this embodiment, the extension part 31 is composed of a upper unit 32 and the lower unit 33.

The force mechanism 34 has a structure that forces the extension part 31 towards the peripheral edge face and the peripheral upper and lower faces of the board 2. In this embodiment, the force mechanism 34 is composed of the 1st supporter 35, which supports the upper unit 32, and the 2nd supporter 36, which supports the lower unit 33, and also includes the 1st linear motion mechanism 37 and the 2nd linear motion mechanism 38. The 1st supporter 35 and the 2nd supporter 36 are each attached to the 1st linear motion mechanism 37 in a way that allows them to move vertically. The 1st linear motion mechanism 37 is attached to 38 in a way that allows it to move horizontally, perpendicular to the peripheral edge face of 2.

The 1st linear motion mechanism 37 is composed of a linear motion guide 37b, which has a linear motion rail 37a attached to it in a vertical direction, a upper slide block 37c, which is attached to the linear motion rail 37a in a sliding manner, and a lower slide block 37d. The linear motion guide 37b has a roughly L-shaped profile when viewed from the side.

The 2nd linear motion mechanism 38 is composed of a linear motion guide 38b, which has a linear motion rail 38a on its horizontal face that is perpendicular to the peripheral edge face of 2, a slide block 38c, which is attached to the linear motion rail 38a in a sliding manner, and a stopper 38d, which restricts the movement of the slide block 38c. The linear motion guide 37b is attached on upper of the slide block 38c.

The 1st supporter 35 has the 1st linear motion part 35a, which is attached to the upper slide block 37c of the 1st linear motion mechanism 37, and a horizontal plate 35b, which is protruded horizontally from the lower part (lower edge) of the 1st linear motion part 35a.

The 2nd supporter 36 has the 2nd linear motion part 36a, which is attached to the lower slide block 37d, a vertical plate 36b, which is vertically protruding from the side (side edge) of the 2nd linear motion part 36a, an attaching axle 36c, which is protruding horizontally from the vertical plate 36b, and a support axle 36d. The attaching axle 36c and the support axle 36d are arranged parallel to each other in the horizontal direction. A stopper 36e is provided in the 2nd linear motion part 36a to restrict the upward movement of the lower slide block 37d.

The 1st force part 39 is composed of a tension coil spring 39a, which is arranged vertically, and the upper end of the tension coil spring 39a is attached to the 1st linear motion part 35a, and the lower end is attached to the 2nd linear motion part 36a. The 2nd force part 40 is composed of a tension coil spring 40a arranged vertically, with the upper end of the tension coil spring 40a attached to the linear motion guide 37b and the lower end attached to the 2nd linear motion part 36a. The 3rd force part 41 is composed of a tension coil spring 41a, which is arranged horizontally, and one end of the tension coil spring 41a is attached to the stopper 38d, and the other end is attached to the slide block 38c.

The upper unit 32 that makes up the extension part 31 is composed of a upper block 32a, the upper extension block 32b, and the 1st attaching member 32c. The upper block 32a has a roughly rectangular prismatic shape and is placed on upper of the horizontal plate 35b of the 1st supporter 35. The upper extension block 32b has a roughly L-shaped profile that covers the upper and one side of the upper block 32a. The 1st attaching member 32c is a component for attaching the upper block 32a and the upper extension block 32b to the horizontal plate 35b.

The 1st attaching member 32c is composed of a stepped male screw with a stepped head 32ca and a screw axle 32cb. The screw axle 32cb is threaded into the upper extension block 32b and the upper block 32a, and the threaded end of the screw axle 32cb is screwed into a screw hole 35ba formed on the upper face of the horizontal plate 35b.

The 1st attaching member 32c is prevented from falling off the upper extension block 32b and the upper block 32a. The screw axle 32cb has a locking section (outer circumference protrusion) to prevent it from falling off. A step is formed in the through-hole so that the relevant engagement part is engaged in the through-hole of the upper block 32a. The upper block 32a and the upper extension block 32b are fixed in place by a fixing member 32d, such as a fixing pin.

The lower unit 33 is composed of a lower block 33a, the lower extension block 33b, the 2nd attaching member 33c, and a 3rd attaching member 33d. The lower block 33a has a axle hole 33aa, through which the attaching axle 36c is passed, and a axle hole 33ab, through which the support axle 36d is passed. The lower extension block 33b has a roughly L-shaped profile that covers the underside and one side of the lower block 33a.

The 2nd attaching member 33c is attached to the tip of the attaching axle 36c, which has the lower block 33a attached, and is a component used to attach the lower block 33a to the attaching axle 36c. The 3rd attaching member 33d is a component used to attach the lower extension block 33b to the lower block 33a.

The 2nd attaching member 33c is a female screw that has a head 33ca and a female screw part 33cb, and is designed to be screwed into the tip thread of the attaching axle 36c. The 3rd attaching member 33d is composed of a stepped male screw with a stepped head 33da and a axle part 33 db. The axle part 33 db is threaded into a recovery part 33e and the lower extension block 33b, and the threaded tip of the axle part 33 db is screwed into the threaded hole formed on the underside of the lower block 33a.

As shown in FIGS. 5, 6 and 7, the upper extension block 32b and the lower extension block 33b have opposing faces on the side mentioned above. On the opposing face, there are a upper face extension member 32ba, which contacts the upper face of the periphery of the board 2, a edge face extension member 32bb, which contacts the edge face of the periphery of the board 2, and a lower face extension member 33ba, which contacts the lower face of the periphery of the board 2.

The extension part 31 is configured to be able to move along the outer periphery of the board while sandwiching the edge face and the upper and lower faces (three sides) of the board with the upper face extension member 32ba, the edge face extension member 32bb, and the lower face extension member 33ba, and to stretch the film-forming liquid into a thin film.

In this embodiment, the upper face extension member 32ba and the edge face extension member 32bb are provided at the lower end of the one side of the upper extension block 32b, and the lower face extension member 33ba is provided at the upper end of the one side of the lower extension block 33b. In another configuration example, the upper extension block 32b may be provided with the upper face extension member 32ba, and the lower extension block 33b may be provided with the lower face extension member 33ba and the edge face extension member 32bb.

The edge face extension member 32bb is positioned opposite the space between the upper face extension member 32ba and the lower face extension member 33ba. In other words, the edge face extension member 32bb is arranged so that it can be pressed against the peripheral edge face of the board 2, which is sandwiched between the upper face extension member 32ba and the lower face extension member 33ba.

On the side facing to the board 2 in the upper face extension member 32ba, the edge face extension member 32bb, and the lower face extension member 33ba, multiple microgrooves are formed along the direction of movement of the coating unit 20. Multiple microgrooves are made up of, for example, cross-sectional wave-shaped grooves or cross-sectional V-shaped grooves, and the spacing and depth of these microgrooves are set appropriately according to the characteristics of the film-forming solution used, such as its viscosity, and the thickness of the film to be formed. For example, when forming a coating film of around 10 μm to 50 μm, set the center-to-center distance of the grooves to around 0.2 mm to 0.3 mm, and the depth of the grooves to around 0.05 mm to 0.1 mm.

The upper face extension member 32ba and the lower face extension member 33ba are fixed to the upper extension block 32b and the lower extension block 33b. For example, the upper face extension member 32ba and the lower face extension member 33ba are composed of circular or semi-circular shaped members that are a few millimeters (e.g. 1 mm to 8mm) wide, which are made by slicing a round bar-shaped bar coater with a diameter of 5 mm to 15 mm, as well as thin plate-shaped members with curved faces.

The upper extension block 32b is formed into a circular, semi-circular, or curved face shape with a width of a few millimeters (e.g., 1 to 8 mm) by processing the lower edge (the part opposite to the lower extension block 33b) on one side of the upper extension block 32b. Similarly, the lower face extension member 33ba is formed into a circular, semi-circular or curved face shape a few millimeters (e.g., 1 to 8 mm) wide by processing the upper edge (the part facing the upper extension block 32b) on one side of the lower extension block 33b.

The coating apparatus 10 is configured to have a plurality of the upper unit 32 and the lower unit 33 with different extension widths as described above, and to be able to be exchanged according to the coating conditions. For example, the coating apparatus 10 is equipped with four types of the upper unit 32 with the upper face extension member 32ba for the above-mentioned extension widths of 1 mm, 3 mm, 5 mm, and 7 mm, and four types of the lower unit 33 with the lower face extension member 33ba for the above-mentioned extension widths of 1 mm, 3 mm, 5 mm, and 7 mm.

Due to this configuration, it is possible to exchange the upper unit 32 and the lower unit 33, which make up the extension part 31, as appropriate, depending on the coating conditions, such as the extension width, etc. In this case, it is preferable to replace the coating part 22 and the coating roller 24 at the same time, depending on the conditions such as the extension width.

The lower extension block 33b is equipped with a recovery route 33bb, a flow channel that collects the film-forming liquid removed from the board 2 by the extension operation. The lower face extension member 33ba is provided on the inner wall face of the recovery route 33bb, and is also configured so that a portion of the edge face extension member 32bb is assembled in the recovery route 33bb in a state where it is in contact with the lower face extension member 33ba.

On one side of the lower part of the lower extension block 33b, the recovery part 33e is provided to collect the film-forming liquid that drips down from the recovery route 33bb. The recovery part 33e is composed of a liquid receiver 33ea, which receives the membrane-forming liquid that drips down from the recovery route 33bb, and a tube 33eb, which extends downward from the liquid receiver 33ea. The lower part of the tube 33eb is inserted into the liquid container 50, and the film-forming liquid that drips down from the lower extension block 33b flows down through the liquid receiver 33ea and the tube 33eb into the liquid container 50.

In the embodiment-related the coating apparatus 10, the upper unit 32 of the extension part 31, which is attached to the horizontal plate 35b of the 1st supporter 35 in a removable manner. The lower unit 33 is attached to the vertical plate 36b in a removable manner while being inserted into the attaching axle 36c and the support axle 36d of the 2nd supporter 36.

Next, the action of attaching and detaching the extension part 31 (the upper unit 32 and the lower unit 33) to the extension mechanism 30 of the coating unit 20 will be explained. As shown in FIG. 8, when removing the upper unit 32 from the extension mechanism 30, turn the stepped head 32ca of the 1st attaching member 32c in the direction of unscrewing (counterclockwise). Then, the tip of the screw axle 32cb of the 1st attaching member 32c will come off the screw hole 35ba of the horizontal plate 35b, and the upper unit 32 will be able to be removed from the horizontal plate 35b. At this time, the upper block 32a and the upper extension block 32b remain locked in place on the screw axle 32cb of the 1st attaching member 32c.

In this way, the upper unit 32 can be removed separately from the lower unit 33. When the upper unit 32 are removed from the extension mechanism 30, the parts that make up the force mechanism 34 are not removed from the extension mechanism 30.

When removing the lower unit 33 from the extension mechanism 30, turn the head 33ca of the 2nd attaching member 33c in the direction of unscrewing (counterclockwise). Then, the female screw part 33cb of the 2nd attaching member 33c comes off the tip thread of the attaching axle 36c, and the lower block 33a becomes a state where it can be pulled out from the attaching axle 36c and the support axle 36d, and the lower unit 33 can be removed from the vertical plate 36b. At this time, the lower extension block 33b and the recovery part 33e remain locked in place on the 3rd attaching member 33d.

In this way, the lower unit 33 can be removed separately from the upper unit 32. When the lower unit 33 are removed from the extension mechanism 30, the parts that make up the force mechanism 34 are not removed from the extension mechanism 30.

According to the coating apparatus 10 described above, the extension part 31 can be removed without removing the force mechanism 34 from the extension mechanism 30. Therefore, it is possible to easily perform maintenance such as replacing only the extension part 31 or cleaning the extension part 31, making it a coating apparatus with excellent maintainability.

According to the coating apparatus 10, since the extension part 31 is configured to be interchangeable with another extension part without removing the force mechanism 34 from the extension mechanism 30. Therefore the extension part 31 can be replaced with another extension part, for example, extension parts of different widths of the film-forming liquid that are extended to the upper and lower faces of the periphery of the board, flexibly according to changes in the type of board to be coated, coating conditions, and other factors, thereby improving the usability of the equipment.

According to the coating apparatus 10, the upper unit 32 of the extension part 31 is supported by the 1st supporter 35 of the force mechanism 34 and the 1st supporter 35 is forced downward by the 1st force part 39. And the lower unit 33 of the extension part 31 is supported by the 2nd supporter 36 of the force mechanism 34 and the 2nd supporter 36 is forced upward by the 2nd force part 40. And the 1st supporter 35 and the 2nd supporter 36 are attached to the 1st linear motion mechanism 37, and the 1st linear motion mechanism 37 attached to the 2nd linear motion mechanism 38 is forced to the side (towards the edge face of the board) of the upper unit 32 and the lower unit 33 by the 3rd force part 41. Therefore the upper unit 32 can be removed from the 1st supporter 35 and the lower unit 33 can be removed from the 2nd supporter 36 separately without removing any of the 1st force part 39, the 2nd force part 40, the 3rd force part 41 from the extension mechanism 30, and maintenance, etc. of the upper unit 32 and the lower unit 33 can be performed separately.

According to the coating apparatus 10, the upper unit 32 is removably attached to the horizontal plate 35b of the 1st supporter 35, and the lower unit 33 is removably attached to the vertical plate 36b, with the lower unit 33 inserted into the attaching axle 36c of the 2nd supporter 36.

Therefore, the upper unit 32 can be removed from the horizontal plate 35b without removing any of the 1st force part 39, the 2nd force part 40, the 3rd force part 41 from the extension mechanism 30. And the lower unit 33 can be removed from the vertical plate 36b in the axis direction of the attaching axle 36c. Therefore, the upper unit 32 and the lower unit 33 can be easily removed without interfering with other equipment components.

According to the coating apparatus 10, by the 1st attaching member 32c of the upper unit 32 The upper block 32a and the upper extension block 32b can be detachably attached to the horizontal plate 35b. By the 2nd attaching member the 2nd attaching member 33c, the lower block the lower block 33a can be detachably attached to the vertical plate 36b with the lower block 33a inserted into the attaching axle 36c. The lower extension block 33b can be attached to the lower block 33a by the 3rd attaching member 33d of the lower unit 33.

The upper face extension member 32ba, the edge face extension member 32bb, and a lower face extension member 33ba are equipped with on the opposite faces of the upper extension block 32b and the lower extension block the lower extension block 33b. Therefore the width of the film-forming liquid stretched on the upper and lower faces can be easily changed, by replacing the upper extension block 32b and the lower extension block 33b according to changes in the board type, coating conditions, and the like.

According to the coating apparatus 10, the coating roller 24 is inserted into the rotating shaft 23 of the coating part 22, and the threaded part 26a of the collection part 26 is screwed onto the screw 23a at the lower end of the rotating shaft 23. The coating roller 24 and the collection part 26 are attachable and detachable from the rotating shaft 23, so the maintenance such as replacement, cleaning, etc. of the coating roller 24 becomes so easy. It is also possible to easily replace the coating roller 24 with another coating roller having a different structure (e.g., height, depth, etc.) of the annular grooves 24a according to changes in the type of board to be coated, coating conditions, etc.

According to the coating apparatus 10, the four coating unit 20 apply the coating to the edges of each side of the board in parallel, greatly reducing the time required to coat the entire board and increasing the efficiency of the coating process. Since it is easy to perform maintenance such as exchanging and cleaning the extension part 31 of the coating unit 20, it is possible to improve the work efficiency of the maintenance of the entire device.

In the embodiment of the coating apparatus 10, the 2nd attaching member 33c was composed of a female screw, and the attaching axle 36c had a tip thread, and these were configured to screw together, but the attaching configuration of the 2nd attaching member 33c is not limited to this.

FIG. 9 is a partially enlarged cross-sectional view showing another attaching configuration example of the 2nd attaching member 33f, (a) is showing the state of the lower block 33a is attached to the attaching axle 36c, (b) and (c) are showing the state of the lower block 33a in the process of being removed from the attaching axle 36c.

In another attaching configuration example, the structure of the 2nd attaching member 33f differs from that of the lower block 33a and the attaching axle 36c, and the structure of attaching the 2nd attaching member 33f to the attaching axle 36c differs.

In another attaching configuration example, the lower block 33a has a short tube 33ac protruding from the opening of the axle hole 33aa, and a flange 33ad is formed at the tip of the short tube 33ac. The attaching axle 36c has a slit 36ca with a two-pronged tip, a mooring 36cb with a protruding shape on the outer face of the tip where The slit 36ca is formed, and a taper 36cc with a diameter that tapers towards the tip from the mooring 36cb. The mooring 36cb is configured to be able to be latched to the edge of the flange 33ad opening.

The 2nd attaching member 33f has a push-button shape with an internal cavity 33fa that can accommodate the flange 33ad and the taper 36cc. The 2nd attaching member 33f has 34fb, which is fitted with the short tube 33ac and is configured to be able to be latched onto the flange 33ad, and the cavity 33fa has a stopper 33fc, which is slanted and can be pushed along the taper 36cc.

As shown in FIG. 9(a), insert the lower block 33a into the attaching axle 36c and push the lower block 33a against the vertical plate 36b (see FIG. 8). The mooring 36cb of the attaching axle 36c is moored to the flange 33ad of the lower block 33a, the lower block 33a is attached to the attaching axle 36c so that it does not come off. Therefore, when attaching, simply push the lower block 33a towards the vertical plate 36b until the flange 33ad engages with the mooring 36cb, and it is possible to attach it easily.

When removing the lower block 33a from the attaching axle 36c, as shown in FIG. 9(b), first push the 2d attaching member the 2nd attaching member 33f toward the lower block 33a. Then, the stopper the stopper 33fc of the cavity 33fa is pressed against the taper 36cc of the attaching axle 36c. Push it in further, the taper 36cc will flex inward due to the stopper 33fc, narrowing the slit 36ca gap, and the mooring 36cb, which was previously held in place by the flange 33ad, will come loose from the flange 33ad, and the taper 36cc will be pushed into the short tube 33ac.

The gap in the slit gradually narrows, the mooring disengages from the opening of the flange, and the mooring is pushed into the short tube. According to the coating apparatus (6), to attach the lower block to the vertical plate, simply insert the axle part into the axle hole in the lower block and push the lower block to the side of the vertical plate until it is in a position where the axle part's mooring engages the opening in the flange.

To remove the lower block from the vertical plate, first push the 2nd attaching member toward the axle part. Then, the stopper of the 2nd attachment member is pressed against the taper of the axle part, the gap in the slit gradually narrows, the mooring disengages from the opening of the flange, and the mooring is pushed into the short tube.

Furthermore, when the 2nd attaching member is pulled from this state in the direction of pulling the 2nd attaching member from the axle part, the short tube port engages the flange, and the lower block can be pulled from the axle part and removed while remaining in this state.

Therefore, the lower block can be easily attached to the vertical plate by the motion of pushing the lower block in, and the lower block can be easily removed from the vertical plate by the simple motion of pushing and pulling the 2nd attachment member.

From this state, when the 2nd attaching member 33f is pulled out from the attaching axle 36c, as shown in FIG. 9(c), a short tube port 33fb of the 2nd attaching member 33f is moored by the flange 33ad. By pulling out the 2nd attaching member 33f and the lower block 33a from the attaching axle 36c while in this locked state, it is possible to remove the lower block 33a from the attaching axle 36c.

According to the another example, the lower block 33a inserted into the attaching axle 36c can be easily attached to the vertical plate 36b (i.e. the lower unit 33 to the 2nd supporter 36) with a simple one-touch action of pushing the lower block 33a against the vertical plate 36b. In addition, after pushing the 2nd attaching member 33f shown in FIG. 9 towards the lower block 33a, it is possible to easily remove the lower block 33a inserted into the attaching axle 36c from the vertical plate 36b by a simple one-touch action of pulling.

Next, the dryer 60 that makes up the coating system 1 will be explained.

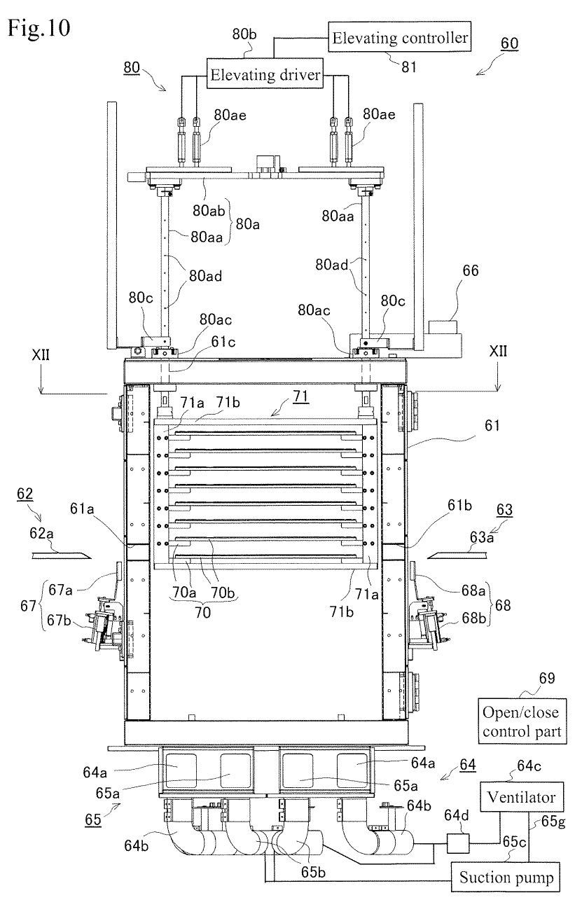

FIG. 10 is a partial cross-sectional front view showing an essential part of a dryer according to an embodiment, showing the internal structure of the side of the drying furnace with the opening and closing door.

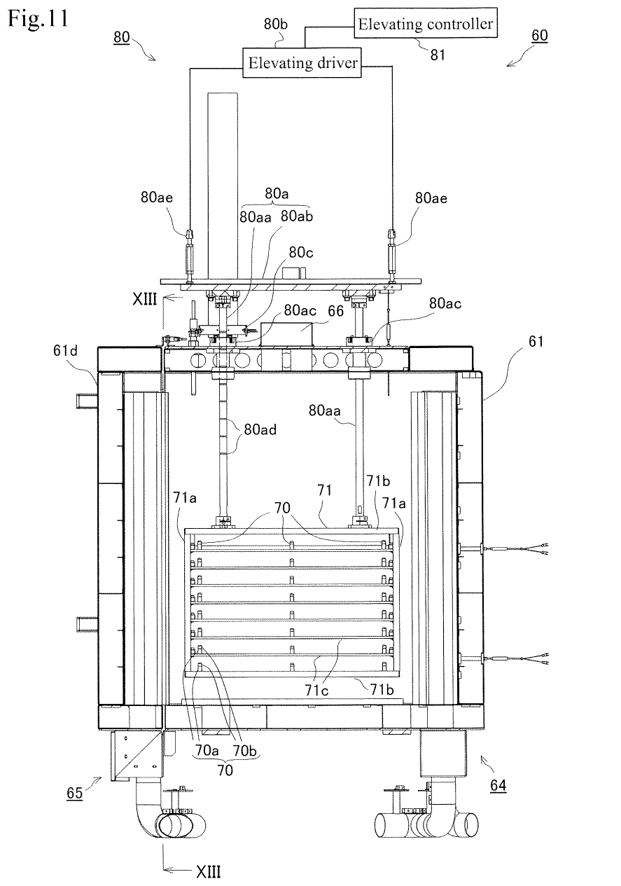

FIG. 11 is a partial cross-sectional side view showing an essential part of a dryer, showing the internal structure of the drying furnace on the side where the board is carried out.

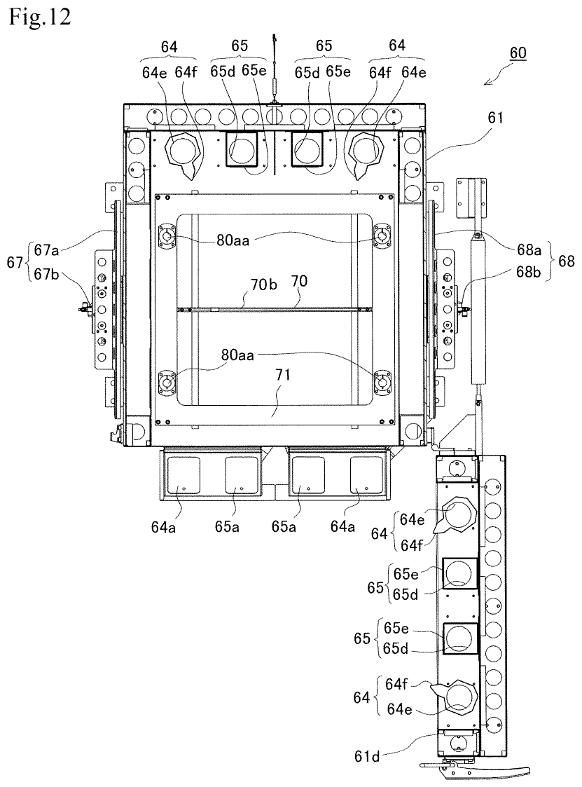

FIG. 12 is a XII-XII partial cross-sectional view in FIG. 10, showing the internal structure with the drying furnace door open.

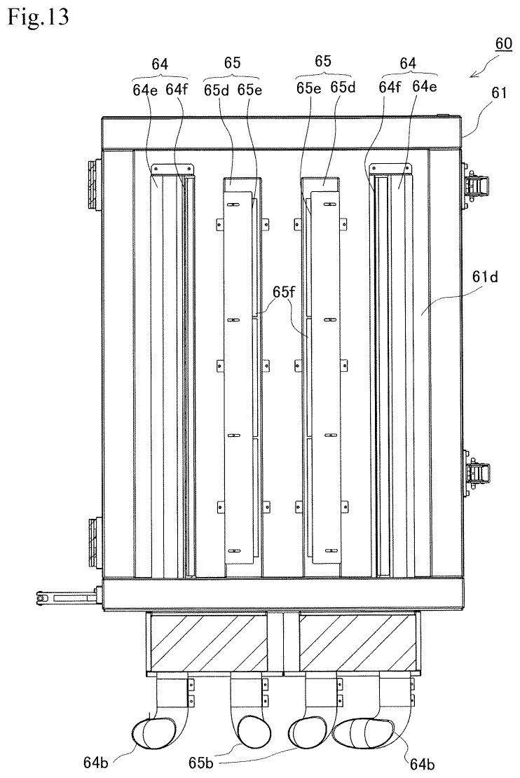

FIG. 13 is a XIII-XIII partial cross-sectional view in FIG. 11, showing the inside of the opening and closing door of the drying furnace.

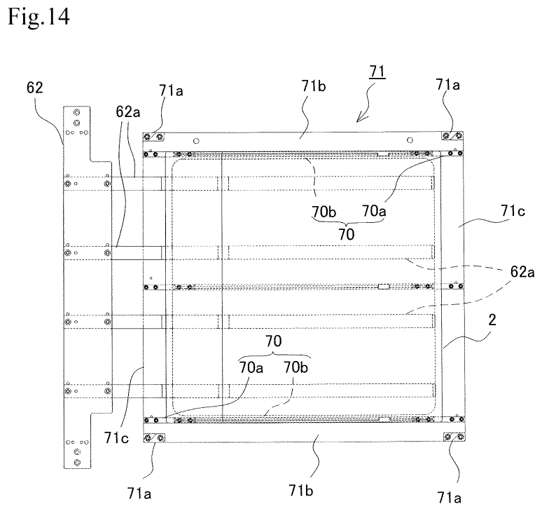

FIG. 14 is a plan view showing the state in which the carry-in forks are inserted into the drying furnace. In FIG. 10˜13, the hatching showing the cross-section of the drying furnace has been omitted for the sake of simplicity.

The drying furnace 61 has a box-shaped, rectangular shape, and the housing shelf 71 with the shelf 70 multiple stages on which the board is placed is arranged inside the drying furnace 61. The carry-in entrance 61a of board is provided on one side of the board carry-in side wall of the drying furnace 61, and the carry-out entrance 61b of board is provided on one side of the board carrying-out side wall of the drying furnace 61. The carry-in entrance 61a has a size that allows the insertion and removal of a carry-in fork 62a, which makes up the carry-in part 62, and the carry-out entrance 61b has a size that allows the insertion and removal of a carry-out fork 63a, which makes up the carry-out part 63.

The housing shelf 71 is composed of a frame that includes a vertical frame 71a and the horizontal frame 71b, which have the edges of a rectangular solid as their framework. In addition, an under frame 71c corresponding to the number of the shelf 70 is constructed between a pair of the vertical frame 71a on the carry-in entrance 61a side, and the under frame 71c corresponding to the number of the shelf 70 is constructed between a pair of the vertical frame 71a on the carry-out entrance 61b side.

Each shelf 70 is composed of a short rectangular bar supporter 70a and a rectangular bar 70b. The supporter 70a is attached in three places, at both ends and in the center of each of the under frame 71c on the carry-in entrance 61a and the carry-out entrance 61b sides, extending in a direction perpendicular to the under frame 71c. The bar 70b is constructed between these carry-in entrance 61a and the carry-out entrance 61b sides.

The positions of the three bar 70b are set with consideration for the size of the circuit board and the location of the empty space where the circuit on the board is not formed.

The carry-in part 62 is composed of the carry-in fork 62a, on which the board is placed, and a linear motion mechanism (not shown in the figure) that moves the carry-in fork 62a back and forth in the carry-in direction of board.

The carry-out part 63 is composed of the carry-out fork 63a, on which the board is placed, and a linear motion mechanism (not shown in the figure) that moves the carry-out fork 63a back and forth in the carry-out direction of board.

As shown in FIG. 14, the carry-in fork 62a has a shape with four teeth, and the positions and intervals of the four teeth are set so that they do not overlap with the three teeth of the bar 70b of the shelf 70. The carry-out fork 63a has the same structure as the carry-in fork 62a.

The elevating mechanism 80, which raises and lowers the housing shelf 71, is equipped with the drying furnace 61, and raising and lowering operation of the housing shelf 71 by the elevating mechanism 80 is controlled by the elevating controller 81. The elevating mechanism 80 is equipped with a supporter 80a, which supports the housing shelf 71 in a suspended state, an elevating driver 80b, which raises and lowers the supporter 80a, and a shelf position detector 80c, which detects the shelf at the height position of the carry-in entrance 61a or the carry-out entrance 61b.

The supporter 80a is composed of an elevating axle 80aa and the elevating plate 80ab. The elevating axle 80aa is installed with its lower end attached to the upper part of the housing shelf 71, and its upper end attached to the elevating plate 80ab, which is installed above the drying furnace 61. On the ceiling wall of the drying furnace 61, an axle hole 61c is formed to allow the elevating axle 80aa to pass through, and an elevating plate 80ac is attached to the axle hole 61c to allow the elevating axle 80aa to pass through.

The shelf position detector 80c is attached to the upper of the elevating plate 80ac. The shelf position detector 80c, for example, is made up of fiber sensors and other photoelectric sensors. The elevating axle 80aa has multiple detecting holes 80ad formed to correspond to the number and spacing of the multiple shelf 70. By detecting that the light emitted from the photoelectric sensor has passed through the detecting hole 80ad, it is possible to detect that the shelf 70 is at the height position of the carry-in entrance 61a or the carry-out entrance 61b. It is possible to detect which of the multiple shelves 70 is at the height position of the carry-in entrance 61a or the carry-out entrance 61b.

For example, the elevating driver 80b is made up of a hoist that has the function of raising and lowering the supporter 80a while the housing shelf 71 is suspended. A hoisting device such as a chain wrapped around a drum that rotates with the power of a servomotor is attached to the elevating plate 80ab. On the upper face of the elevating plate 80ab, an attaching device 80ae is provided for attaching the hoisting device.

Based on the detection signal from the shelf position detector 80c and the detection signal of the hanging height of the supporter 80a using the elevating driver 80b, the elevating controller 81 controls the movement of the shelf 70 that carries in the board from among the multiple stages of the shelf 70 to the height position of the carry-in entrance 61a, and controls the movement of the shelf 70 that carries out the board to the height position of the carry-out entrance 61b.

When the board is carried in, the elevating controller 81 controls the elevating driver 80b to position the shelf 70 at a height of the carry-in entrance 61a, where the board is carried in. After that, the elevating controller 81 controls the up-and-down movement of the housing shelf 71 so that the board that has been brought in with the carry-in entrance 61a and the carry-in part 62 placed on it is placed on the shelf 70.

When the board is carried out, the elevating controller 81 controls the elevating driver 80b to position the shelf 70 at a height of the carry-out entrance 61b, where the board is carried out. After that, the elevating controller 81 controls the vertical movement of the housing shelf 71 so that the board placed on the shelf 70 is transferred to the upper of the carry-out part 63, which has been inserted from the carry-out entrance 61b.

The carry-in entrance opening/closing part 67 is provided on the outer wall face of the board input side of the drying furnace 61, and the carry-out entrance opening/closing part 68 is provided on the outer wall face of the board output side of the drying furnace 61. The carry-in entrance opening/closing part 67 is equipped with a lid 67a, which is used to block the carry-in entrance 61a, and a moving mechanism 67b, which is used to move the lid 67a in the opening and closing direction. The carry-out entrance opening/closing part 68 is equipped with a lid 68a, which is used to block the carry-out entrance 61b, and a moving mechanism 68b, which is used to move the lid 68a in the opening and closing direction. The opening and closing of the lid 67a by the moving mechanism 67b and the opening and closing of the lid 68a by the moving mechanism 68b are controlled by the open/close control part 69.

The elevating controller 81 and the open/close control part 69 are configured so that they can exchange control signals with each other. For example, after positioning the shelf 70, which will carry-in the board to the height position of the carry-in entrance 61a, at the elevating controller 81, send an open command to the open/close control part 69 to open the lid 68a, which is currently closed. After positioning the shelf 70, which will carry-out the board to the height position of the carry-out entrance 61b, at the elevating controller 81, send an open command to the open/close control part 69 to open the lid 68a, which is currently closing the carry-out entrance 61b.

The ventilation 64, which supplies gas (hot air) to the drying furnace 61, and the suction part 65, which sucks out the gas inside the drying furnace 61, are provided on both side walls that intersect with the side wall of the board feed side of the drying furnace 61, i.e., the wall of the one-sided door 61d and the opposite wall.

A ventilation mouth 64a of the ventilation 64 and a suction mouth 65a of the suction part 65 are provided on both sides of the floor face of the drying furnace 61, and a ventilator 64c is connected to the ventilation mouth 64a via a duct 64b, and a suction pump 65c is connected to the suction mouth 65a via a duct 65b. The dust collection filter 64d is provided between the ventilation mouth 64a and the ventilator 64c.

The suction pump 65c and the ventilator 64c are connected by a duct 65g, and the gas sucked in by the suction pump 65c is sent to the ventilator 64c, so that the gas (hot air) inside the drying furnace 61 can circulate. As shown in FIGS. 12 and 13, the ventilation 64 has a vertical ventilation tube 64e (approximately the same height as the height within the drying furnace 61) installed near the four corners of the drying furnace 61, and a long, a vertical spouting mouth 64f (approximately a beak shape) protruding from the side of the ventilation tube 64e into the furnace. The lower of the ventilation tube 64e is connected to the ventilation mouth 64a. The spouting mouth 64f is formed as a narrow slit, and is oriented along the edge of the board placed on the shelf 70, so that a circulating flow of gas is formed within the drying furnace 61. The slit width (approximately 1 mm or more) of the spouting mouth 64f can be adjusted.

As shown in FIGS. 12 and 13, the suction part 65 has a vertical suction tube 65d (of a height approximately the same as the height inside the drying furnace 61) installed next to the ventilation 64, and a vertical suction slit 65e installed on the side of the suction tube 65d, with the lower part of the suction tube 65d connected to the suction mouth 65a.

By shifting the position of a slit width adjustment plate 65f, the slit width (approximately 1 mm or more) of the suction slit 65e can be adjusted. It is also possible to shift the slit width adjustment plate 65f diagonally and fix it in place, which makes it possible to adjust the shape of the slit, for example, so that the upper slit is wider than the lower one.

The exhaust part 66 is installed in the ceiling wall of the drying furnace 61 and is connected to an exhaust duct not shown in the diagram, allowing some of the gas inside the drying furnace 61 to be exhausted outside. The suction pump 65c is equipped with a function to take in outside air, such as an outside air intake valve, and is configured to be able to take in outside air as needed, making it possible to adjust the humidity and other conditions inside the drying furnace 61.

The operation of the dryer 60 related to the embodiment is explained. First, the process of carry-in the board into the drying furnace 61 are explained. When the coating process of the film-forming liquid on the peripheral area including the edge of the board is completed at the coating apparatus 10, the board is transferred to the carry-in fork 62a and placed on top of it by the board transfer part 14 of the coating apparatus 10 (see FIG. 1).

When the board is placed on the carry-in fork 62a, the operation of carrying-in the board into the drying furnace 61 is performed. Based on the state (history) of the carry-in and carry-out of the board into and out of the drying furnace 61, the elevating controller 81 determines the position of the shelf 70 where the board is carried in, and moves the housing shelf 71 up and down using the elevating mechanism 80 so that the position of the shelf 70 is at the height of the carry-in entrance 61a. At the same time, the open/close control part 69 drives the moving mechanism 67b of the carry-in entrance opening/closing part 67, causing the lid 67a to move downward so that the carry-in entrance 61a opens.

After that, the carry-in part 62 moves the carry-in fork 62a, which has the board on it, horizontally towards the carry-in entrance 61a and inserts the carry-in fork 62a from the carry-in entrance 61a to the specified position. In this state, the board placed on the carry-in fork 62a is not placed on the shelf 70, and there is a gap between the underside of the board and the shelf 70.

From this state, drive the elevating mechanism 80 to slightly raise the housing shelf 71 and place the board on top of the shelf 70 so that the board is placed on top of the shelf 70. After the board is placed on top of the shelf 70, the carry-in fork 62a is moved horizontally in the opposite direction to the carry in direction, and the carry-in fork 62a are pulled out from the carry-in entrance 61a, and the carry-in fork 62a is moved to a predetermined position.

After that, the open/close control part 69 drives the moving mechanism 67b of the carry-in entrance opening/closing part 67, and the lid 67a is moved upwards so that the carry-in entrance 61a is in the closed state, and the board carry-in operation is completed. And, depending on the timing at which the board is transported from the coating apparatus 10, the above operation is repeated.

Next, the process of drying the board in the drying furnace 61 is explained. Hot air (e.g. air at a temperature of around 80° C. to 200° C.) from the ventilator 64c with a heater function is sent to the ventilation tube 64e, which is connected to the ventilation mouth 64a placed in the four corners of the drying furnace 61 via the dust collection filte 64d and the duct 64b. The hot air fed into the ventilation tube 64e is blown out through the vertical slit-shaped the spouting mouth 64f into the drying furnace 61.

Since the ventilation 64 is arranged in the four corners of the drying furnace 61 and the spouting mouth 64f is directed in a certain direction along each side of the board, an airflow that flows in a certain direction along the four sides of the board (in other words, circulates in a certain direction within the drying furnace 61) is generated.

At the same time as the air is blown into the drying furnace 61, some of the hot air inside the drying furnace 61 is sucked out through the suction slit 65e of the suction part 65 and sent to the suction pump 65c via the suction tube 65d, the suction mouth 65a and the duct 65b. From the exhaust part 66 set in the drying furnace 61, the gas inside the drying furnace 61 is appropriately exhausted, and at the same time, outside air is appropriately introduced from the intake valve (not shown in the figure) set in the suction pump 65c, and the conditions such as humidity and temperature inside the drying furnace 61 are adjusted.

Next, the operation for carrying out the board from the drying furnace 61 is explained. After the board is carried into the drying furnace 61, the specified drying time elapses, and then the board is carried out. Based on the state (history) of the carry-in of the board to the drying furnace 61, the elevating controller 81 determines the location of the shelf 70, where the board to be carry-out is placed, and drives the elevating mechanism 80 to move the housing shelf 71 up and down so that the location of the shelf 70 is at the height of the carry-out entrance 61b. At the same time, the open/close control part 69 drives the moving mechanism 68b of the carry-out entrance opening/closing part 68, causing the lid 68a to move downward so that the carry-out entrance 61b opens.

After that, the carry-out part 63 moves the carry-out fork 63a horizontally towards the carry-out entrance 61b and inserts the carry-out fork 63a from the carry-out entrance 61b to the specified position. In this state, the carry-out fork 63a is located below the shelf 70, where the board to be carried out is placed, and there is a gap between the underside of the board and the carry-out fork 63a.

From this state, drive the elevating mechanism 80 to slightly down the housing shelf 71 and place the board on top of the carry-out fork 63a so that the board is placed on top of the carry-out fork 63a. After the board is placed on top of the carry-out fork 63a, the carry-out fork 63a is moved horizontally to the carry-out direction, and the carry-out fork 63a are pulled out from the carry-out entrance 61b, and the carry-out fork 63a is moved to a predetermined position. After that, the open/close control part 69 drives the moving mechanism 68b of the carry-out entrance opening/closing part 68, and the lid 68a is moved upwards so that the carry-out entrance 61b is in the closed state, and the board carry-out operation is completed. And, the above operation is repeated at the timing when the specified drying time has elapsed.

According to the dryer 60 related to the embodiment, it is configured to raise and lower the housing shelf 71, which has the multiple shelf 70 within the drying furnace 61. Therefore, there is no need to raise or lower the carry-in fork 62a of the carry-in part 62 or the carry-out fork 63a of the carry-out part 63, and the structure of the device can be simplified, making it possible to save space and make the device more compact.

According to the dryer 60, by controlling the vertical movement of the housing shelf 71 using the elevating controller 81, it is possible to accurately place the board that has been placed on the carry-in fork 62a and carried in from the carry-in entrance 61a onto the shelf 70, which is at the height of the carry-in entrance 61a. The board placed on the shelf 70 at a height of the carry-out entrance 61b can be accurately transferred to the carry-out fork 63a, which has been inserted from the carry-out entrance 61b, and the board can be accurately and efficiently carried-in and carried-out.

According to the dryer 60, it is detected which of the multiple shelves 70 is at the height position of the carry-in entrance 61a or the carry-out entrance 61b by the shelf position detector 80c. Therefore, it is possible to accurately detect the shelf 70 that are loaded with the boards that are brought in at the carry-in fork 62a and the shelf 70 that are loaded with the boards that are transferred to the carry-out fork 63a, and it is possible to improve the accuracy of the board carry-in and carry-out operations.

Next, the UV irradiation device 90 that makes up the coating system 1 is explained. The UV irradiation device 90 is a device for curing the film-forming liquid by irradiating UV rays on the periphery of the board, which has been coated with the film-forming liquid and dried as shown in FIG. 1. The UV irradiation device 90 is made up of the UV irradiation stage 91, the positioning unit 92, the board transfer part 93, the conveyor 94, the light irradiation unit 95, the rotation mechanism 96, and the irradiation controller 98.

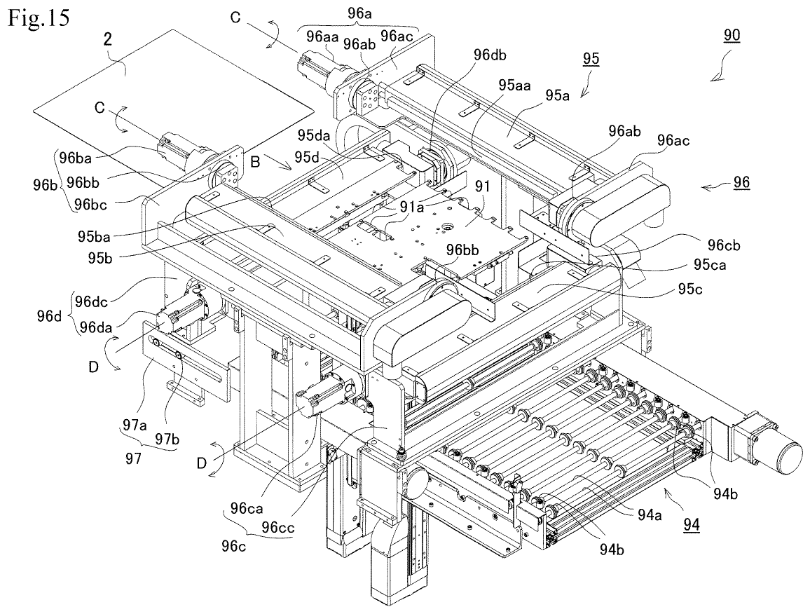

First, the structure of the light irradiation unit 95, which is the main part of the UV irradiation device 90, will be explained. FIG. 15 is a slanted view showing an essential part of the light irradiation unit 95 of the UV irradiation device 90. The light irradiation unit 95 is composed of the 1st light irradiation unit pair 95a, 95b, and the 2nd light irradiation unit pair 95c, 95d which are arranged opposite each other at different heights around lift space of the UV irradiation stage 91.

The 1st light irradiation unit pair 95a and 95b are arranged in a direction parallel to the transport direction B of the board 2, and are provided with a irradiation part 95aa and a irradiation part 95ba, which are arranged in a row with a large number of UV irradiation lamps (e.g., LED lamps), and are configured so that the irradiation state (ON, OFF) can be switched, etc., by the irradiation controller 98. The 2nd light irradiation unit pair 95c and 95d are arranged in a direction that is perpendicular to the transport direction B of the board 2, and are equipped with a irradiation part 95ca and a irradiation part 95da, which have a large number of UV irradiation lamps arranged in a row, and are configured so that the irradiation state (ON, OFF) can be switched, etc., by the irradiation controller 98. The UV irradiation lamps mentioned above use LEDs that emit UV rays in the long wavelength range of 320 to 400 nm, which is effective for curing the film-forming liquid.

The rotation mechanism 96 is composed of the 1st rotation mechanism pair 96a and 96b, which rotate the 1st light irradiation unit pair 95a and 95b, and the 2nd rotation mechanism pair 96c and 96d, which rotate the 2nd light irradiation unit pair 95c and 95d.

The 1st rotation mechanism pair 96a and 96b are configured to rotate the 1st light irradiation unit pair 95a and 95b around an axis C that is parallel to the transport direction B of the board 2. The 1st rotation mechanism pair 96a and 96b are provided with a rotation motor 96aa and 96ba, the rotation member 96ab and 96bb, which rotate together with the rotation axis of the rotation motor 96aa and 96ba, and a fix frame 96ac and 96bc to which the rotation motor 96aa, 96ba, the rotation member 96ab and 96bb are attached. The 1st light irradiation unit pairs 95a and 95b are attached to the rotation members 96ab and 96bb.

The 2nd rotation mechanism pair 96c and 96d are configured to rotate the 2nd light irradiation unit pair 95c and 95d around an axis D that is perpendicular to the transport direction B of the board 2. The 2nd rotation mechanism pair 96c and 96d are equipped with a rotation motor 96ca and 96da, a rotation member 96cb and 96 db, which rotate together rotation axle of the rotation motor 96ca and 96da, and a fix frame 96cc and 96dc, to which the rotation motor 96ca, 96da, the rotation member 96cb and 96 db are attached.

The UV irradiation device 90 is further provided with a transport mechanism 97 that advances or retracts at least one of the 2nd rotation mechanism pair 96c and 96d (in this embodiment, the 2nd rotation mechanism pair 96d) in the direction B of the board transport. The transport mechanism 97 is composed of a linear motion mechanism that can move the 2nd rotation mechanism pair 96d forward or backward in the transport direction B of the board 2. The linear motion mechanism is composed of a guide 97a, which allows the 2nd rotation mechanism pair 96d to move forward and backward in the transport direction B of the board 2, and a slide part 97b, which moves the 2nd rotation mechanism pair 96d along the guide 97a.

The conveyor 94 that transports the board 2 is arranged below the UV irradiation stage 91, and the conveyor 94 is, for example, composed of a magnet-driven conveyor, and has multiple roller axle 94a arranged at predetermined intervals in the transport direction B of the board 2, and multiple narrow width roller 94b inserted into each of these roller axle 94a. According to the conveyor 94, the magnetic force of the magnet can be used to drive the roller axle 94a without contact, reducing wear on the drive unit and suppressing dust generation.

The UV irradiation stage 91 has an aperture 91a in a position opposite to multiple narrow width roller 94b of the conveyor 94. By lowering the UV irradiation stage 91 and having the narrow width roller 94b appear above the aperture 91a, it is possible to place the board 2, which is above the UV irradiation stage 91, on top of the narrow width roller 94b.

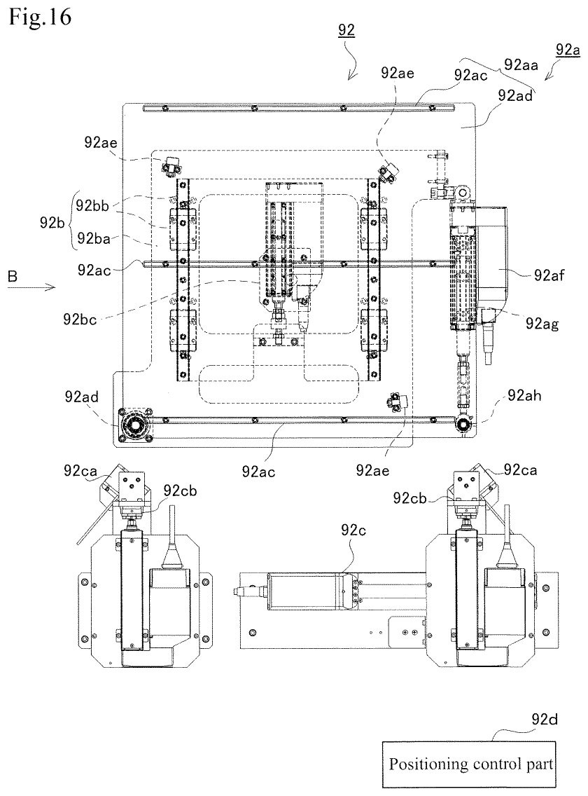

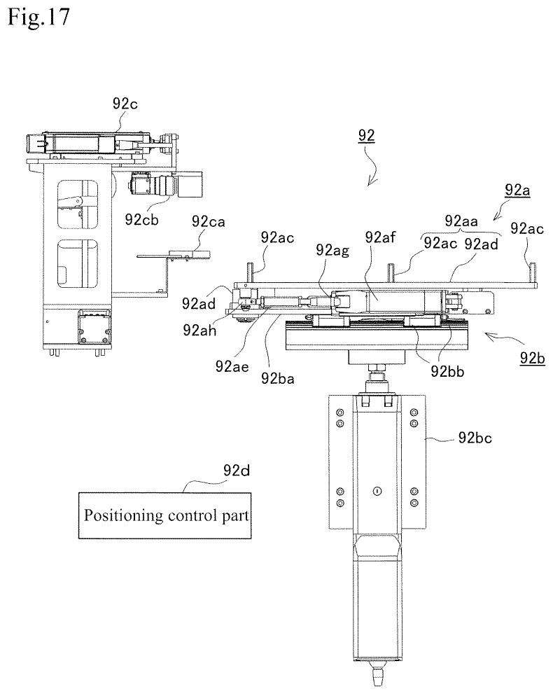

Next, the composition of the positioning unit 92, which is placed in front of the light irradiation unit 95 is explained. FIG. 16 is a plan view showing an essential part of a positioning unit of a UV irradiation device, FIG. 17 is a side view showing an essential part of a positioning unit. The positioning unit 92 has a mechanism that positions the board in the correct position before moving the board carried-out from the dryer 60 onto the UV irradiation stage 91.

Above the positioning unit 92, the board transfer part 93 (see FIG. 1) is provided. the board transfer part 93 moves the board that has been positioned at the positioning unit 92 onto the UV irradiation stage 91. For example, the board transfer part 93 is equipped with a board holding part that holds the board, a horizontal movement mechanism that moves the board holding part back and forth in the board transport direction, and a vertical movement mechanism that moves the board holding part back and forth in the vertical direction (none of which are shown in the figure). The board holding part is equipped with a vacuum holding device that holds the board.

The positioning unit 92 has an upper table unit 92a, which can be rotated with the board placed on it, and a lower table unit 92b, which is located at the lower of the upper table unit 92a. The lower table unit 92b is equipped with a mechanism that moves the upper table unit 92a in a predetermined direction (a horizontal direction that is perpendicular to the board transport direction B).

Furthermore, the positioning unit 92 is equipped with a corner detection part 92c and a positioning control part 92d. The corner detection part 92c has a function to detect the orientation and position of the two corners of one side of the board placed on the upper table unit 92a. The positioning control part 92d has a function that drives the upper table unit 92a and/or the lower table unit 92b so that the orientation and position of the two corners of the board detected by the corner detection part 92c become the specified orientation and position.

The upper table unit 92a has a place table 92aa, on which the board is placed, a rotation axis 92ad, which is the pivot axis of the place table 92aa, a roller 92ae, which supports the place table 92aa while rotating, and a rotation driver 92af, which rotates the place table 92aa.

The rotation axis 92ad is located on the lower of one of the four corners of the place table 92aa. The roller 92ae is provided on the lower face of the other three corners of the place table 92aa. The rotation driver 92af has a function that rotates the place table 92aa around the rotation axis 92ad.

The place table 92aa is composed of a rectangle flat plate 92ab and three board placing part 92ac flat bars attached to the top of the flat plate 92ab. The board placing part 92ac is attached facing the direction B of the board transport.

The rotation driver 92af is composed of a rod-type (radial cylinder) robocylinder 92ag and (rod-end bearing) a bearing 92ah, with one end of the robocylinder 92ag (the tip of the rod) attached to the bearing 92ah.

The robocylinder 92ag is attached to the underside of the side opposite the side where the place table 92aa is attached. The bearing 92ah is attached to the corner of the place table 92aa where the rotation axis 92ad is attached and the corner adjacent to the board transport direction B.

By controlling the stroke length of rod of the robocylinder 92ag, the place table 92aa rotates around the rotation axis 92ad, making it possible to adjust the orientation (angle) of the board together with the table angle.

The lower table unit 92b has a support table 92ba, which supports the place table 92aa, and a linear motion mechanism 92bb, which can be adjusted to a position that is perpendicular to the board transport direction B.

The lower end of the rotation axis 92ad is attached to the support table 92ba, and the other end of the robocylinder 92ag is attached. The lower table unit 92b is further equipped with a elevating mechanism 92bc, which is located at the lower of the linear motion mechanism 92bb. the elevating mechanism 92bc makes it possible to raise and lower the positioning unit 92 in the vertical direction.

The corner detection part 92c has two lighting part 92ca that illuminate the two corners of one side of the board from below, and two image capture part 92cb that are positioned opposite these the lighting part 92ca and capture images of the two corners of the board from above.

The positioning control part 92d controls the upper table unit 92a and/or the lower table unit 92b so that the orientation and position of the two corners of the board imaged by the two image capture part 92cb are in the specified orientation and position.

Next, the light irradiation operation performed by the UV irradiation device 90 related to the embodiment will be explained.

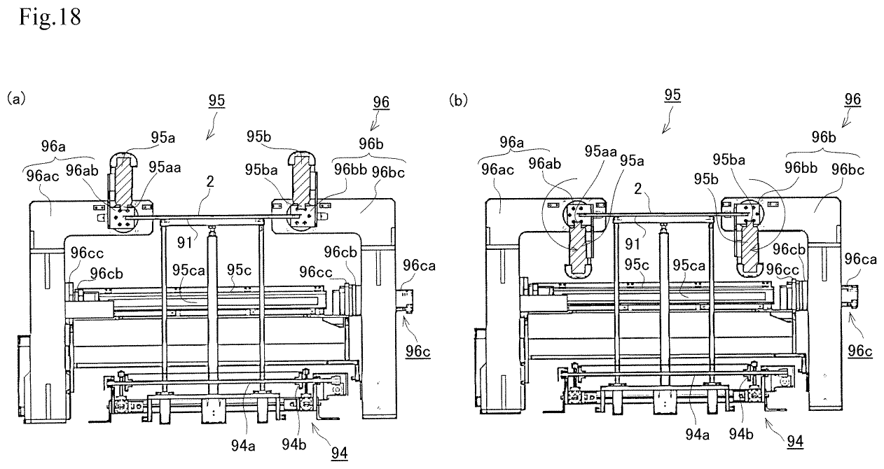

FIG. 18 is a partial cross-sectional side view showing light irradiation operation by the 1st light irradiation unit pairs 95a, 95b.

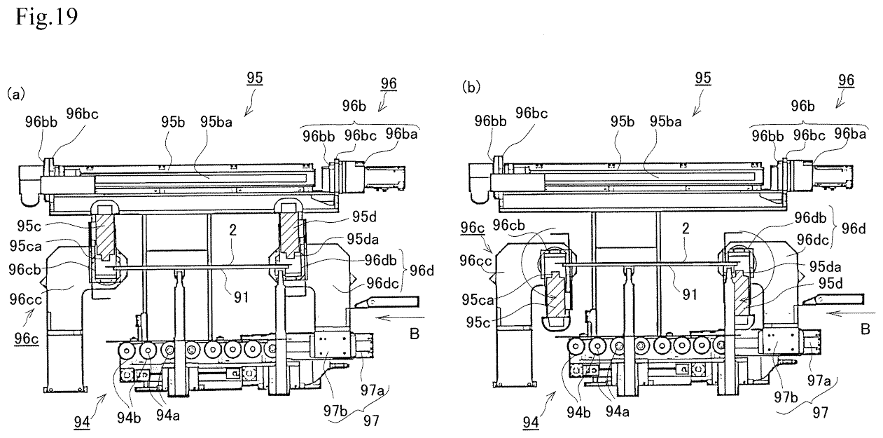

FIG. 19 is a partial cross-sectional side view showing light irradiation operation by the 2nd light irradiation unit pairs 95c, 95d.

When 2 is carried out from the carry-out entrance 61b of the dryer 60 by the carry-out fork 63a, the board 2 is transferred from the carry-out fork 63a to the positioning unit 92 above by the board transfer part 93, and the board 2 is placed on the place table 92aa. At this time, the place table 92aa is moved to a predetermined height position (e.g., between the lighting part 92ca and the image capture part 92cb of the corner detection part 92c).

Next, the corner detection part 92c activates the lighting part 92ca and the image capture part 92cb to capture images of the two corners of one side of the board 2 placed on the place table 92aa. The positioning control part 92d performs board positioning control by operating the upper table unit 92a and/or the lower table unit 92b so that the orientation and position of the two corners of one side of the board 2 captured image become the predetermined orientation and position.

When positioning of the board 2 by the positioning unit 92 is complete, the board 2 is transferred from the positioning unit 92 to the above of the UV irradiation stage 91 by the board transfer part 93, and the board 2 is placed on the UV irradiation stage 91. When the board 2 is placed on top of the UV irradiation stage 91, the irradiation controller 98 controls the UV irradiation stage 91 to rise to the height of the 1st light irradiation unit pair 95a and 95b, as shown in FIG. 18.

And the irradiation controller 98 controls the rotation motor 96aa of the 1st rotation mechanism pair 96a and the rotation motor 96ba of the 1st rotation mechanism pair 96b to drive. Rotate the 1st light irradiation unit pair 95a and 95b until the irradiation part 95aa of the 1st light irradiation unit pair 95a and the irradiation part 95ba of the 1st light irradiation unit pair 95b are in a state of almost vertical downward (as shown in FIG. 18(a)). At this time, the light-irradiated faces of the irradiation part 95aa and the irradiation part 95ba are in close proximity to the upper faces of the two sides of the board 2 parallel to the transport direction B.

From this state, the irradiation controller 98 starts controlling the irradiation of UV rays from the irradiation part 95aa of the 1st light irradiation unit pair 95a and the irradiation part 95ba of the 1st light irradiation unit pair 95b, and UV rays is irradiated on the upper face of the two sides of the board 2. If the board 2 is thin, UV rays is also irradiated on the upper and lower faces of the periphery of the board 2, as well as on the edge faces of the periphery.

Once the UV rays irradiation on the upper face of the periphery of the board 2 is complete, the irradiation controller 98 will control the rotation motor 96aa of the 1st rotation mechanism pair 96a and the rotation motor 96ba of the 1st rotation mechanism pair 96b to drive. Then, rotate the irradiation part 95aa of the 1st light irradiation unit pair 95a and the irradiation part 95ba of the 1st light irradiation unit pair 95b by about 180 degrees until are in a state of being almost vertically upward (as shown in FIG. 18(b)). At this time, the light-irradiated faces of the irradiation part 95aa and the irradiation part 95ba are in close proximity to the lower faces of the two edges of the board 2 that are parallel to the transport direction B.

From this state, the irradiation controller 98 starts to control the irradiation of ultraviolet rays from the irradiation part 95aa of the 1st light irradiation unit pair 95a and the irradiation part 95ba of the 1st light irradiation unit pair 95b, and ultraviolet rays are irradiated on the lower face of the two sides of the board 2. If the board 2 is thin, UV rays will also be irradiated on the edge face of the circumference, as well as the lower face of the circumference of the board 2.

Once the UV irradiation of the lower edge of the two sides parallel to the board transport direction B is complete, the irradiation controller 98 will cause the UV irradiation stage 91 to descend to the height position of the 2nd light irradiation unit pair 95c and 95d. Furthermore, the irradiation controller 98 drives the rotation motor 96ca of the 2nd rotation mechanism pair 96c and the rotation motor 96da of the 2nd rotation mechanism pair 96d.

Then, rotate the irradiation part 95ca of the 2nd light irradiation unit pair 95c and the irradiation part 95da of the 2nd light irradiation unit pair 95d until are in a state of almost vertical downward (as shown in FIG. 19(a)). At this time, the light-irradiated faces of the irradiation part 95ca and the irradiation part 95da are in close proximity to the upper faces of the two sides of the board 2, which are in a direction perpendicular to the transport direction B.

From this state, the irradiation controller 98 starts to control the irradiation of ultraviolet rays from the irradiation part 95ca of the 2nd light irradiation unit pair 95c and the irradiation part 95da of the 2nd light irradiation unit pair 95d, and ultraviolet rays are irradiated on the upper faces of the other two sides of the board 2. If the board 2 is thin, UV rays will also be irradiated on the edge face of the circumference, as well as the upper face of the circumference of the board 2.

Once the UV rays irradiation on the upper face of the periphery of the board 2 is complete, the irradiation controller 98 will control the rotation motor 96ca of the 2nd rotation mechanism pair 96c and the rotation motor 96da of the 2nd rotation mechanism pair 96d to drive. Then, rotate the 2nd light irradiation unit pair 95c and 95d by about 180 degrees until the irradiation part 95ca of the 2nd light irradiation unit pair 95c and the irradiation part 95da of the 2nd light irradiation unit pair 95d are in a state of being almost vertically upward (as shown in FIG. 19(b)). At this time, the light-irradiated faces of the irradiation part 95ca and the irradiation part 95da are in close proximity to the lower faces of the other two sides of the board 2.

From this state, the irradiation controller 98 starts to control the irradiation of ultraviolet rays from the irradiation part 95ca of the 2nd light irradiation unit pair 95c and the irradiation part 95da of the 2nd light irradiation unit pair 95d, and ultraviolet rays are irradiated on the lower face of the other two sides of the board 2. If the board 2 is thin, UV rays is also irradiated on the edge face of the circumference as well as the lower face of the circumference of the board 2.

When the UV irradiation of the lower periphery of the board 2 is complete, the irradiation controller 98 lowers the UV irradiation stage 91 to the height of the conveyor 94, and the board 2 on the UV irradiation stage 91 is placed on the narrow width roller 94b of the conveyor 94. After that, the conveyor 94 is driven, and the board 2 is carried out from the light irradiation unit 95, and the light irradiation process is complete.

Furthermore, the orientation of the light irradiation unit 95 (the 1st light irradiation unit pair 95a, 95b, and the 2nd light irradiation unit pair 95c, 95d) relative to the periphery of the board 2 when exposed to UV rays is not limited to the above forms (roughly vertical upwards, roughly vertical downwards). The orientation (angle) of the 1st light irradiation unit pair 95a, 95b, and the 2nd light irradiation unit pair 95c, 95d relative to the periphery of the board 2 is set as appropriate according to the conditions such as the thickness of the object to be coated and the coating width on the upper and lower faces of the periphery of the board 2.

For example, if the thickness of the board 2 is greater than the specified thickness, when UV irradiation of the upper face of the peripheral area of the two sides of the board 2 is completed in the state shown in FIG. 18(a) above, the irradiation controller 98 controls the rotation motor 96aa and 96ba of the 1st rotation mechanism pair 96a and 96b to drive them, and then rotates the 1st light irradiation unit pair 95a and 95b by about 90 degrees until the irradiation part 95aa of the 1st light irradiation unit pair 95a and the irradiation part 95ba of the 1 st light irradiation unit pair 95b face each other in the horizontal direction.

Then, from the state where the light-irradiated faces of the irradiation part 95aa and the irradiation part 95ba are in close proximity to the peripheral edge faces of the board 2, the irradiation controller 98 starts controlling the irradiation of UV rays from the irradiation part 95aa and the irradiation part 95ba of the 1st light irradiation unit pair 95a and 95b, and irradiates UV rays to the peripheral edge faces of the two sides of the board 2 parallel to the transport direction of the board 2.

Similarly, when UV irradiation of the other two sides of the periphery of the board 2 is complete in the state shown in FIG. 19(a) above, the irradiation controller 98 controls the rotation motor 96ca of the 2nd rotation mechanism pair 96c and the rotation motor 96da of the 2nd rotation mechanism pair 96d to drive, and rotates the 2nd light irradiation unit pair 95c and the 2nd light irradiation unit pair 95d by about 90 degrees until the irradiation part 95ca of the 2nd light irradiation unit pair 95c and the irradiation part 95da of the 2nd light irradiation unit pair 95d face each other in the horizontal direction.

Then, from the state where the light-irradiated faces of the irradiation part 95ca and the irradiation part 95da are in close proximity to the peripheral edge faces of the board 2, the irradiation controller 98 starts to control the irradiation of UV rays from the irradiation part 95ca and the irradiation part 95da of the 2nd light irradiation unit pair 95c and the 2nd light irradiation unit pair 95d, and UV rays is irradiated to the peripheral edge faces of the other two sides of the board 2.

In another form, the irradiation controller 98 may control the direction (angle) of each irradiation part of the light irradiation unit 95 to an angle of less than 90 degrees with respect to the upper and lower faces of the board 2, and irradiate ultraviolet rays from an oblique direction toward the upper and edge faces of the peripheral part of the board 2 and toward the lower and edge faces of the peripheral part of the board 2, respectively.

According to the UV irradiation device 90, the light irradiation unit 95 is arranged around the elevation space of the UV irradiation stage 91, and the light irradiation unit 95 is configured to rotate so that the light irradiation face of the light irradiation unit 95 is in close contact with the upper and lower peripheral faces of the board placed on the UV irradiation stage 91. Therefore, there is no need to move the board horizontally when irradiating it with light, and light can be irradiated evenly and efficiently on the edge faces and upper and lower lower faces of each side of the board, allowing the film-forming liquid to be cured evenly and efficiently.

In addition, according to the UV irradiation device 90, by moving the UV irradiation stage 91, which has a board placed on it at the height positions the 1st light irradiation unit pair 95a and 95b, and rotating the 1st light irradiation unit pair 95a and 95b by the 1st rotation mechanism pair 96a and 96b, light irradiation can be performed uniformly and efficiently on the upper face of the periphery, the edge face of the periphery, and the lower face of the periphery of the board, which is in a parallel relationship with the transport direction B of the board.

By moving the UV irradiation stage 91, which has a board placed on it at a height position different from the 1st light irradiation unit pair 95a and 95b, and rotating the 2nd light irradiation unit pair 95c and 95d by the 2nd rotation mechanism pair 96c and 96d, it is possible to perform uniform and efficient light irradiation on the upper face of the periphery, the edge face of the periphery, and the lower face of the periphery of the board, which is in a right angle relationship with the transport direction B of the board. Therefore, the UV irradiation device 90 can be made more compact, and the device configuration can be made more compact.

In addition, according to the UV irradiation device 90, by advancing or retracting by the transport mechanism 97 at least one of the 2nd rotation mechanism pair 96c and 96d in the board transport direction, the arrangement interval of the 2nd rotation mechanism pair 96c and 96d can be adjusted according to the size of the board, etc., and it can be applied to boards of different sizes.

In addition, according to the UV irradiation device 90, when the UV irradiation stage 91 is lowered, the narrow width roller 94b of the conveyor 94 can be made to face the aperture 91a. Therefore, by simply lowering the UV irradiation stage 91, the board on the UV irradiation stage 91 can be transferred to the conveyor 94, and the efficiency of transferring the board to the conveyor 94 and carrying it out can be improved.

In addition, according to the UV irradiation device 90, which is equipped with the positioning unit 92, the upper table unit 92a and/or the lower table unit 92b are controlled so that the orientation and position of the corner of the board detected by the corner detection part 92c become the predetermined orientation and position, so the orientation and/or position of the board can be adjusted.

In addition, because the corner detection part 92c is configured to image the corner of the board illuminated by the lighting part 92ca with the image capture part 92cb, the direction and position of the corner of the board can be detected more accurately based on the image captured.

Then, by the positioning control part 92d, the upper table unit 92a and/or the lower table unit 92b are driven so that the orientation and position of the corner of the board imaged by the image capture part 92cb become the specified orientation and position, and the orientation and/or position of the board is adjusted, so that the orientation and/or position of the board can be adjusted with even greater precision.

The upper table unit 92a is configured so that the place table 92aa can be rotated by the rotation driver 92af around the rotation axis 92ad, allowing fine adjustment of the orientation (angle) of the board. In addition, the lower table unit 92b is configured so that the support table 92ba, which supports the place table 92aa, can be fine-tuned in a direction perpendicular to the board movement direction. Therefore, the accuracy of the board orientation and positioning can be improved.

By the positioning unit 92, the orientation and/or position of the board is adjusted before the board is moved onto the UV irradiation stage 91, and the board that has been adjusted can be moved onto the UV irradiation stage 91 by the board transfer part 93. Therefore, the board can be placed on top of the UV irradiation stage 91 with the board positioned accurately, and light can be accurately irradiated onto the upper, edge, and lower face of periphery of the board using the light irradiation unit 95.

According to the coating system 1 for the embodiment, it is composed of the coating apparatus 10, the dryer 60, and the UV irradiation device 90, so it is a system that has the above-mentioned effect of the coating apparatus 10, the above-mentioned effect of the dryer 60, and the above-mentioned effect of the UV irradiation device 90. Therefore, it is superior to conventional systems in terms of maintainability, takes up less space, and can efficiently perform drying and curing processes using light irradiation, making it possible to construct a coating system that is suitable for integration into the board manufacturing process.

Furthermore, the coating system related to this invention does not need to be composed of a coating apparatus, a dryer, and a UV irradiation device. The coating system for another configuration may comprise a coating apparatus and a dryer, and the coating system for another embodiment may comprise a coating apparatus and a UV irradiation device.

### Industrial Applicability

This invention can be used in a wide range of fields, including the electronic circuit board industry and the electronic equipment industry, which handle various types of boards such as printed circuit boards, metal boards, package boards, and glass boards.

### DESCRIPTION OF REFERENCE SIGNS

1: Coating system
2: Board
10: Coating apparatus
11: Conveyor
12: Positioning unit
13: Coating stage (supporting part)
14: Board transfer part
15: Transport unit (Transport means)
15a: X-axis linear motion mechanism
15b: Y-axis linear motion mechanism
16: Coating control unit
17: Controller
20: Coating unit
21: Coating mechanism
22: Coating part
23: Rotating shaft
23a: Screw
24: Coating roller
24a: Annular groove
24b: Axle hole
25: 1Liquid supply part
25a: Tube attachment
25b: Liquid ejection part
25ba: Nozzle hole
26: Collection part
26a: Threaded part
26aa: Screw hole
26b: Liquid receiver
26c: Linkage
26d: Tube
30: Extension mechanism
31: Extension part
32: Upper unit
32a: Upper block
32b: Upper extension block
32ba: Upper face extension member
32bb: Edge face extension member
32c: 1st attaching member
32ca: Stepped head
32cb: Screw axle
32d: Fixing member
33: Lower unit
33a: Lower block
33aa: Axle hole
33ab: Axle hole
33ac: Short tube
33ad: Flange
33b: Lower extension block
33ba: Lower face extension member
33bb: Recovery route
33c: 2nd attaching member
33ca: Head
33cb: Female screw part
33d: 3rd attaching member
33da: Stepped head
33 db: Axle part
33f: 2nd attaching member
33fa: Cavity
33fb: Short tube port
33fc: Stopper
33e: Recovery part
33ea: Liquid receiver
33eb: Tube
34: Force mechanism
35: 1st supporter
35a: 1st linear motion part
35b: Horizontal plate
35ba: Screw hole
36: 2nd supporter
36a: 2nd linear motion part
36b: Vertical plate
36c: Attaching axle
36ca: Slit
36cb: Mooring
36cc: Taper
36d: Support axle
36e: Stopper
37: 1st linear motion mechanism
37a: Linear motion rail
37b: Linear motion guide
37c: Upper slide block
37d: Lower slide block
38: 2nd linear motion mechanism
38a: Linear motion rail
38b: Linear motion guide
38c: Slide block
38d: Stopper
39: 1st force part
39a: Tension coil spring
40: 2nd force part
40a: Tension coil spring
41: 3rd force part
41a: Tension coil spring
50: Liquid container
51: Lid
51a: Tube attachment
52: Under box
53: Box receiving base
54: Transfer pump
55: Attaching member
60: Dryer
61: Drying furnace
61a: Carry-in entrance
61b: Carry-out entrance
61c: Axle hole
61d: Door
62: Carry-in part (Board carry in means)
62a: Carry-in fork
63: Carry-out part (Board carry out means)
63a: Carry-out fork
64: Ventilation
64a: Ventilation mouth
64b: Duct
64c: Ventilator
64d: Dust collection filter
64e: Ventilation tube
64f: Spouting mouth
65: Suction part
65a: Suction mouth
65b: Duct
65c: Suction pump
65d: Suction tube
65e: Suction slit
65f: Slit width adjustment plate
65g: Duct
66: Exhaust part
67: Carry-in entrance opening/closing part
67a: Lid
67b: Moving mechanism
68: Carry-out entrance opening/closing part
68a: Lid
68b: Moving mechanism
69: Open/close control part
70: Shelf
70a: Supporter
70b: Bar
71: Housing shelf
71a: Vertical frame
71b: Horizontal frame
71c: Under frame
80: Elevating mechanism
80a: Supporter
80aa: Elevating axle
80ab: Elevating plate
80ac: Linear bush
80ad: Detecting hole
80ae: Attaching device
80b: Elevating driver
80c: Shelf position detector
81: Elevating controller
90: UV irradiation device (light irradiation device)
91: UV irradiation stage (elevating stage)
91a: Aperture
92: Positioning unit (positioning means)
92a: Upper table unit
92aa: Place table
92ab: Flat plate
92ac: Board placing part
92ad: Rotation axis
92ae: Roller
92af: Rotation driver
92ag: Robocylinder
92ah: Bearing
92b: Lower table unit
92ba: Support table
92bb: Linear motion mechanism (linear motion mechanism part)
92bc: Elevating mechanism
92c: Corner detection part (corner detection means)
92ca: Lighting part
92cb: Image capture part
92d: Positioning control part
93: Board transfer part
94: Conveyor
94a: Roller axle
94b: Narrow width roller
95: Light irradiation unit
95a,95b: 1st light irradiation unit pair
95aa,95ba: Irradiation part
95c,95d: 2nd light irradiation unit pair
95ca,95da: Irradiation part
96: Rotation mechanism
96a,96b: 1st rotation mechanism pair
96aa,96ba: Rotation motor
96ab,96bb: Rotation member
96ac, 96bc: Fix frame
96c,96d: 2nd rotation mechanism pair
96ca, 96da: Rotation motor
96cb,96db: Rotation member
96cc, 96dc: Fix frame
97: Transport mechanism
97a: gGide
97b: Slide part
98: Irradiation controller
A: Moving direction of coating unit
B: Transport direction of a bord
C, D: Axis(rotation center axis)

1. A coating apparatus for applying a film-forming liquid to the periphery of a board while moving the board and a coating unit relative to each other, the coating apparatus comprising:
the coating unit, wherein
the coating unit comprises a coating mechanism and an extension mechanism,
the coating mechanism has a coating part that applies the film-forming liquid to at least the peripheral edge surface of the board,
the extension mechanism has an extension part that extends the film-forming liquid applied by the coating part into a thin film on the edge surface of the periphery and the upper and lower surfaces of the periphery of the board, and a force mechanism that forces the extension part towards the edge surface of the periphery and the upper and lower surfaces of the periphery of the board,
the extension part is removable without removing the force mechanism from the extension mechanism.

2. The coating apparatus according to claim 1, wherein the extension part is configured to be interchangeable with another extension part without removing the force mechanism from the extension mechanism.

3. The coating apparatus according to claim 1, wherein the extension part comprises an upper unit and a lower unit,
the force mechanism comprises;
a 1st supporter supporting said upper unit,
a 2nd supporter supporting said lower unit,
a 1st linear motion mechanism to which the 1st supporter and the 2nd support are each movably attached in a vertical direction,
a 2nd linear motion mechanism to which the 1st linear motion mechanism is movably attached in a horizontal direction orthogonal to the peripheral edge surface of the board,
a 1st force part that forces the 1st supporter downwardly,
a 2nd force part that forces the 2nd supporter upwards; and
a 3rd force part that forces the 1st linear motion mechanism attached to the 2nd linear motion mechanism towards the upper unit and the lower unit.

4. The coating apparatus according to claim 3, wherein the 1st supporter has a 1st linear motion part attached to the 1st linear motion mechanism and a horizontal plate strip protruding from the lower part of the 1st linear motion part,
the 2nd support part has a 2nd linear motion part attached to the 1st linear motion mechanism, a vertical plate protruding from the side of the 2nd linear motion part, and an axle protruding horizontally from the vertical plate,
the upper unit is detachably attached to the horizontal plate, and
the lower unit is detachably attached to the vertical plate with the lower unit inserted into the axle.

5. The coating apparatus according to claim 4, wherein the upper unit comprises an upper block that is positioned above the horizontal plate, an L-shaped upper extension block that covers the top and one side of the upper block, and a 1st attaching member that attaches the upper block and the upper extension block to the horizontal plate,
the lower unit comprises a lower block having an axle hole through which the axle is inserted, an L-shaped lower extension block that covers the lower surface and one side of the lower block, a 2nd attaching member that is attached to the tip of the axle to which the lower block is inserted, and a 3rd attaching member that attach the lower extension block to the lower block,
the upper extension block and the lower extension block have facing surfaces on one side, and
the facing surfaces are equipped with an upper face extension member that contacts the upper peripheral surface of the board, an edge face extension member that contacts the peripheral edge surface of the board, and a lower face extension member that contacts the lower peripheral surface of the board.

6. The coating apparatus according to claim 5, wherein the lower block has a short tube protruding from the opening of the axle hole,
the short tube has a flange at its tip,
the axle part has a cutout formed on the tip side, a mooring formed on the outer circumference of the tip where the cutout is formed, and a taper formed on the tip side from the mooring,
the mooring is configured to be able to engage the opening of the flange, and
the 2nd attaching member has a cavity that can accommodate the flange and the taper, a short tube port that can be inserted into the short tube and can be engaged with the flange, and an inclined stopper that can be pressed along the taper in the cavity.

7. The coating apparatus according to claim 1, wherein the coating part has a rotating shaft with a screw at its lower end, a coating roller with an annular groove on its outer circumference and an axle hole in the center through which the rotating shaft is inserted, a liquid supply part located close to the outer circumference of the coating roller to supply the film-forming liquid to the annular groove, and a collection part to collect the film-forming liquid dripping down from the coating roller,
the collection part has a threaded part that has a screw hole that can be screwed into the screw and fixes the coating roller to the rotating shaft,
a liquid receiver that is located below the threaded part, and a linkage that connects the threaded part and the liquid receiver so that their central axis are the same, and
the coating roller and the collection part are attachable and detachable from the rotating shaft.

8. The coating apparatus according to claim 1, comprises:
a supporter that supports the board,
the coating units arranged around the supporter,
transport means for transporting each of these coating units along the edge of the bord supported by the supporter,
a coating control unit that controls the operation of each of these transporting means and each of the coating units, wherein
the coating control unit perform controls by transporting each coating unit along the edge of the board by each of the transport means,
while applying the film-forming liquid to at least the peripheral edge surface of the board by the coating part of the coating units, and
while extending the film-forming liquid to the peripheral edge surface and the upper and lower surfaces of the peripheral portion of the board by the extension part in a thin film shape.

9. A dryer having a drying furnace for drying a board coated with a film-forming liquid by a coating apparatus, the dryer comprising:
a housing shelf with multiple shelves on which the board is placed, located in the drying furnace,
a carrying-in entrance opening/closing part provided on the side of the board carrying-in side of the drying furnace that opens and closes the carrying-in entrance where the board carrying-in means is put in and out,
a carrying-out entrance opening/closing part provided on the side of the board carrying-out side of the drying furnace that opens and closes the carrying-out entrance where the board carrying-out means is put in and out,
an opening/closing control part that controls the opening/closing operations by the carrying-in entrance opening/closing part and the carrying-out entrance opening/closing part,
an elevating mechanism to lift and lower the housing shelf, and
an elevating controller that controls the lifting and lowering operation of the housing shelf by the elevating mechanism.

10. The dryer according to claim 9, wherein
the elevation control unit controls the elevation operation of the housing shelves so that, at the time of board carry in, the shelves to which the board are to be carry in are positioned at the height of the carry in entrance among the multiple shelves, and then the board that are brought in by the board carry in means are placed on the shelves,
and controls the elevation operation of the housing shelves so that, at the time of board carry out, the shelves to which the board are to be carry out are positioned at the height of the carry out entrance among the multiple shelves, and then the board on the shelves are transferred to the board carry out means.

11. The dryer according to claim 9, wherein the elevating mechanism comprises:
a supporter for the housing shelf;
an elevating driver to elevate the supporter; and
a shelf position detector to detect the presence of the shelf at the height position of the carry in entrance or the carry out entrance.

12. A light irradiation device for irradiating light to the periphery of a board on which a film-forming liquid has been applied by a coating apparatus to cure the film-forming liquid, the light irradiation device comprising:
a elevating stage that can be elevated with the board placed on it,
a light irradiation unit that is positioned around elevating space of the elevating stage and irradiates light to the periphery of the board, and
a rotation mechanism to rotate the light irradiation unit so that the light irradiation surface of the light irradiation unit is in close proximity to and facing at least the upper surface of the periphery and the lower surface of the periphery of the board.

13. The light irradiation device according to claim 12, wherein the light irradiation units comprising a 1st light irradiation unit pair and a 2nd light irradiation unit pair arranged in opposing positions at different heights around the elevating space, wherein
the 1st light irradiation units pair is arranged in a direction parallel to the board transport direction,
the 2nd light irradiation units pair is positioned in a direction orthogonal to the board transport direction, and
the rotation mechanism comprising a 1st rotation mechanism pair that rotates the 1st light irradiation unit pair and a 2nd rotating mechanism pair that rotates the 2nd light irradiation unit pair.

14. The light irradiation device according to claim 13, further comprising:
a transport mechanism for advancing or retracting at least one of the 2nd rotation mechanisms pair in the transport direction of the board.

15. The light irradiation device according to claim 12, wherein
a conveyor for transporting the board is located below the elevating stage,
the conveyor has narrow width rollers arranged in the direction of conveyance of the board,
the elevating stage has an aperture at a position opposite to the narrow width rollers of the conveyor to bring these narrow width rollers to the top of the elevating stage.

16. The light irradiation device according to claim 12, further comprising:
positioning means for positioning the board before moving it onto the elevating stage, and
transport means for moving the board, which has been positioned as specified by the positioning means, onto the elevating stage.

17. The light irradiation device according to claim 16, wherein the positioning means comprises:
upper table unit that can rotate with the board placed on it,
a lower table unit located under the upper table unit and capable of moving the upper table unit linearly in a predetermined direction,
a corner detection means for detecting the orientation and position of a corner of a board placed on the upper table unit, and
a positioning control part that drives the upper table unit and/or the lower table unit so that the orientation and position of the corners of the board detected by the corner detection means are in the specified orientation and position.

18. The light irradiation device according to claim 17, wherein the upper table unit comprises:
a place table on which the board is placed,
a rotation axis provided on one corner lower face of the place table,
a roller provided on the other corner lower face of the place table, and
a rotation driver to rotate the place table around the rotation axis,
wherein the lower table comprises:
a support table that supports the place table, and
a linear motion mechanism part that can adjust the support table in a direction perpendicular to the direction of movement of the board,
wherein the rotation axis and the rotation drive are attached to the support table.

19. The light irradiation device according to claim 17, wherein the corner detection means comprises:
a lighting part that illuminates from below toward the corners of the board, and
an imaging capture part provided in a position opposite to the lighting part, which captures images of the corners of the board from above, wherein
the positioning control part drives the upper table unit and/or the lower table unit so that the orientation and position of the corners of the board as imaged by the image capture part are in a predetermined orientation and position.

20. A coating system comprising a coating apparatus according to claim 1 and a dryer having a drying furnace for drying a board coated with a film-forming liquid by a coating apparatus, a housing shelf with multiple shelves on which the board is placed, located in the drying furnace, a carrying-in entrance opening/closing part provided on the side of the board carrying-in side of the drying furnace that opens and closes the carrying-in entrance where the board carrying-in means is put in and out, a carrying-out entrance opening/closing part provided on the side of the board carrying-out side of the drying furnace that opens and closes the carrying-out entrance where the board carrying-out means is put in and out, an opening/closing control part that controls the opening/closing operations by the carrying-in entrance opening/closing part and the carrying-out entrance opening/closing part, an elevating mechanism to lift and lower the housing shelf, and an elevating controller that controls the lifting and lowering operation of the housing shelf by the elevating mechanism.

21. A coating system comprising a coating apparatus according to claim 1 and a light irradiation device for irradiating light to the periphery of a board on which a film-forming liquid has been applied by a coating apparatus to cure the film-forming liquid including an elevating stage that can be elevated with the board placed on it, a light irradiation unit that is positioned around elevating space of the elevating stage and irradiates light to the periphery of the board, and a rotation mechanism to rotate the light irradiation unit so that the light irradiation surface of the light irradiation unit is in close proximity to and facing at least the upper surface of the periphery and the lower surface of the periphery of the board.

22. A coating system according to claim 20 further comprising a light irradiation device for irradiating light to the periphery of a board on which a film-forming liquid has been applied by a coating apparatus to cure the film-forming liquid including an elevating stage that can be elevated with the board placed on it, a light irradiation unit that is positioned around elevating space of the elevating stage and irradiates light to the periphery of the board, and a rotation mechanism to rotate the light irradiation unit so that the light irradiation surface of the light irradiation unit is in close proximity to and facing at least the upper surface of the periphery and the lower surface of the periphery of the board.
